(19) United States
(12) Patent Application Publication
(10) Pub. No.: US 2025/0294879 A1
(43) Pub. Date: Sep. 18, 2025

(54) DISPLAY APPARATUS

(71) Applicant: Samsung Display Co., Ltd., Yongin-si (KR)

(72) Inventor: Junsu Park, Yongin-si (KR)

(21) Appl. No.: 19/071,400

(22) Filed: Mar. 5, 2025

(30) Foreign Application Priority Data
Mar. 13, 2024 (KR) 10-2024-0035428

(51) Int. Cl. H10D 86/40; H10H 29/32; H10K 59/121

(52) U.S. Cl. CPC H10D 86/421; H10H 29/32; H10K 59/1213

(57) ABSTRACT

A display apparatus includes a substrate, and a first transistor above the substrate, and including a first electrode, and a semiconductor layer above or below the first electrode, and including a first channel area overlapping the first electrode and including a first sub-area and a second sub-area forming line symmetry with respect to a virtual straight line extending in a first direction, the first sub-area and the second sub-area including first channel portions having channel lengths in a second direction crossing the first direction, second channel portions having channel lengths in a third direction crossing the first direction and the second direction, and crossing portions connecting the first channel portions to the second channel portions.

### CROSS-REFERENCE TO RELATED APPLICATION

The present application claims priority to, and the benefit of, Korean Patent Applications No. 10-2024-0035428, filed on Mar. 13, 2024, in the Korean Intellectual Property Office, the entire disclosure of which is incorporated herein by reference.

### BACKGROUND

### 1. Field

One or more embodiments relate to a display apparatus.

### 2. Description of the Related Art

With the development of display apparatuses for visually displaying electrical signals, various display apparatuses with excellent characteristics, such as small thickness, small weight, reduced power consumption, etc., have been introduced. For example, flexible display apparatuses which may be curved, folded, or rolled have been introduced. Recently, display apparatuses of various structures, such as stretchable display apparatuses, which may be changed to have various shapes have been actively researched and developed.

Such display apparatuses may include a plurality of pixels and transistors, capacitors, and lines configured to control the brightness, etc. of each of the pixels.

### SUMMARY

When a channel area of a transistor is deformed due to stretching of a display apparatus, a brightness of a pixel including the deformed channel area may be increased or decreased. One or more embodiments include a display apparatus for displaying a high-quality image by reducing brightness deviation of pixels due to stretching of the display apparatus. However, this objective is an example, and the scope of the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a substrate, and a first transistor above the substrate, and including a first electrode, and a semiconductor layer above or below the first electrode, and including a first channel area overlapping the first electrode and including a first sub-area and a second sub-area forming line symmetry with respect to a virtual straight line extending in a first direction, the first sub-area and the second sub-area including first channel portions having channel lengths in a second direction crossing the first direction, second channel portions having channel lengths in a third direction crossing the first direction and the second direction, and crossing portions connecting the first channel portions to the second channel portions.

A sum of the channel lengths of the first channel portions may be substantially equal to a sum of the channel lengths of the second channel portions.

A channel width of the first channel portions may be substantially equal to a channel width of the second channel portions.

The first direction may bisect an angle made by the second direction and the third direction.

The second direction and the third direction may be substantially orthogonal to each other.

The substrate may be configured to be stretched in at least one of the second direction or the third direction.

The substrate may include an elastomer.

In stretching the substrate in the second direction, a sum of the channel lengths of the first channel portions may be increased, and a sum of the channel lengths of the second channel portions may be decreased, wherein, in stretching the substrate in the third direction, the sum of the channel lengths of the first channel portions is decreased, and the sum of the channel lengths of the second channel portions is increased.

In stretching the substrate in the second direction, a channel width of the first channel portions may be decreased and a channel width of the second channel portions may be increased, wherein, in stretching the substrate in the third direction, the channel width of the first channel portions is increased and the channel width of the second channel portions is decreased.

The display apparatus may further include a first insulating layer and a second insulating layer facing each other with the semiconductor layer therebetween, wherein the first insulating layer and the second insulating layer include an elastomer.

The semiconductor layer may include an oxide-based semiconductor material or a silicon-based semiconductor material.

The semiconductor layer may include a stretchable semiconductor material.

The semiconductor layer may include a carbon nanotube or an organic semiconductor material.

The first electrode may include a stretchable conductive material.

The first electrode may include a conductive composite or a liquid metal material.

At least a portion of the first channel area may have a stair shape in a plan view.

The display apparatus may further include a second transistor above the substrate, and including a second electrode overlapping the semiconductor layer, wherein the semiconductor layer includes a second channel area overlapping the second electrode, and wherein a channel length of the second channel area is less than a channel length of the first channel area.

The semiconductor layer may further include a first area and a second area extending in the third direction, and spaced apart from each other in the second direction, wherein the first channel area is between the first area and the second area.

The semiconductor layer may further include a first conductive area and a second conductive area extending in the first direction, and spaced apart from each other in a fourth direction crossing the first direction, wherein the first channel area is between the first conductive area and the second conductive area.

The display apparatus may further include a light-emitting diode electrically connected to the first transistor.

Aspects other than those described above will become apparent based on the drawings, the scope of the claims, and the detailed descriptions of the disclosure.

### BRIEF DESCRIPTION OF THE DRAWINGS

The above and other aspects of embodiments of the disclosure will be more apparent from the following description taken in conjunction with the accompanying drawings, in which:

FIG. 1 is a schematic perspective view of a display apparatus according to one or more embodiments;

FIGS. 2A and 2B are perspective views of the display apparatus of FIG. 1 stretched in a first direction;

FIG. 2C is a perspective view of the display apparatus of FIG. 1 stretched in a second direction;

FIG. 2D is a perspective view of the display apparatus of FIG. 1 stretched in a first direction and a second direction;

FIG. 2E is a perspective view of the display apparatus of FIG. 1 stretched in a third direction;

FIG. 3 is a schematic plan view of a display apparatus according to one or more embodiments;

FIGS. 4A to 4C are respectively equivalent circuit diagrams of a pixel of a display apparatus according to one or more embodiments;

FIG. 5A is a schematic cross-sectional view of a portion of a display apparatus according to one or more embodiments;

FIG. 5B is a schematic cross-sectional view of the portion of the display apparatus of FIG. 5A stretched in a first direction;

FIGS. 6A and 6B are respectively schematic cross-sectional views of a light-emitting diode of a display apparatus according to one or more embodiments;

FIG. 7 is a schematic plan view of a semiconductor layer of a display apparatus according to one or more embodiments;

FIG. 8A is a plan view of the semiconductor layer of FIG. 7 stretched in a first direction;

FIG. 8B is a plan view of the semiconductor layer of FIG. 7 stretched in a second direction;

FIG. 8C is a plan view of the semiconductor layer of FIG. 7 stretched in a first direction and a second direction;

FIGS. 9 to 12 are respectively schematic plan views of a semiconductor layer of a display apparatus according to one or more embodiments;

FIG. 13 is a schematic plan view of a semiconductor layer of a display apparatus according to one or more embodiments; and

FIGS. 14A to 14G are respectively schematic perspective views of examples of an electronic device including a display apparatus according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that the present disclosure covers all modifications, equivalents, and replacements within the idea and technical scope of the present disclosure, that each of the features of embodiments of the present disclosure may be combined with each other, in part or in whole, and technically various interlocking and operating are possible, and that each embodiment may be implemented independently of each other, or may be implemented together in an association, unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and/or the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

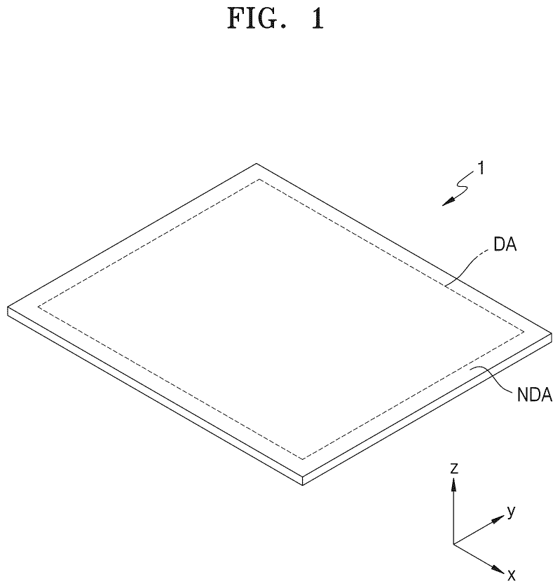

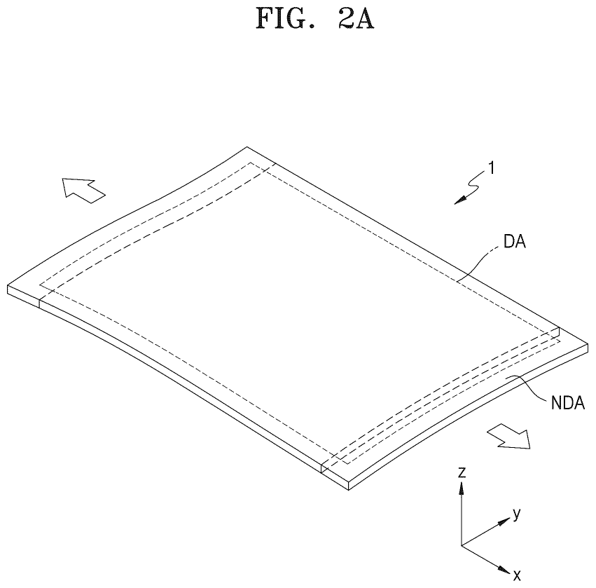

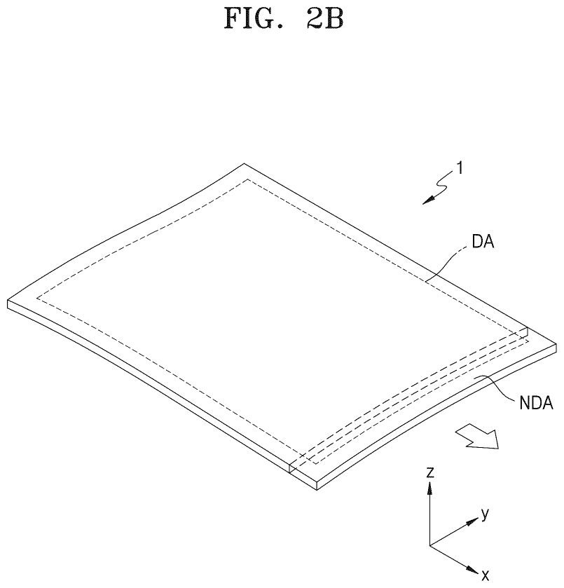

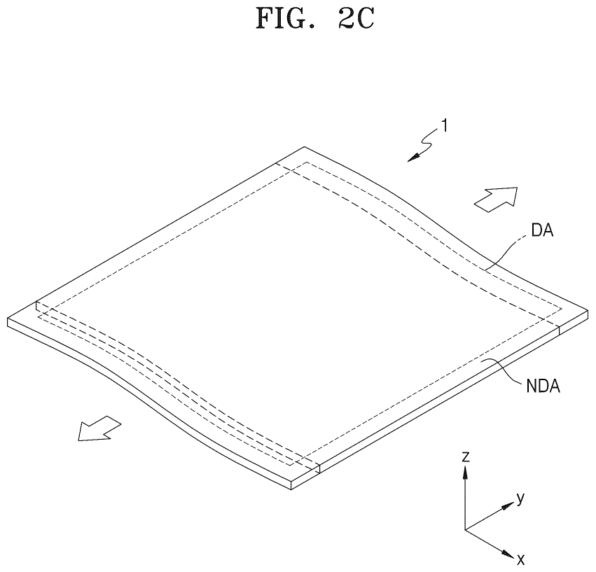

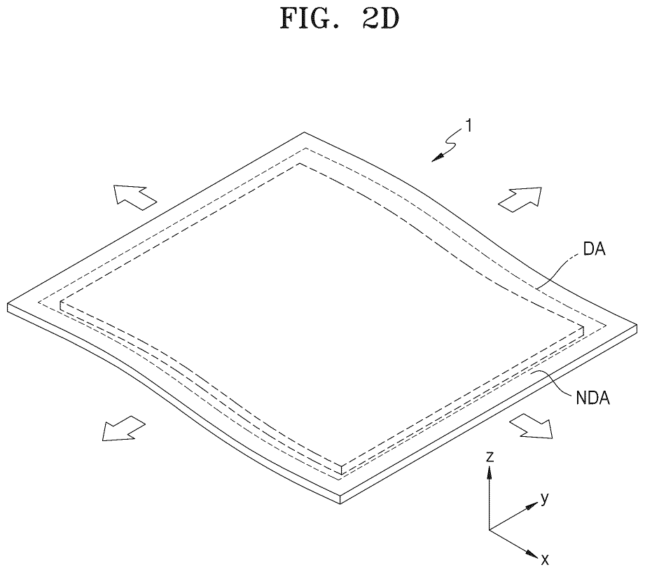

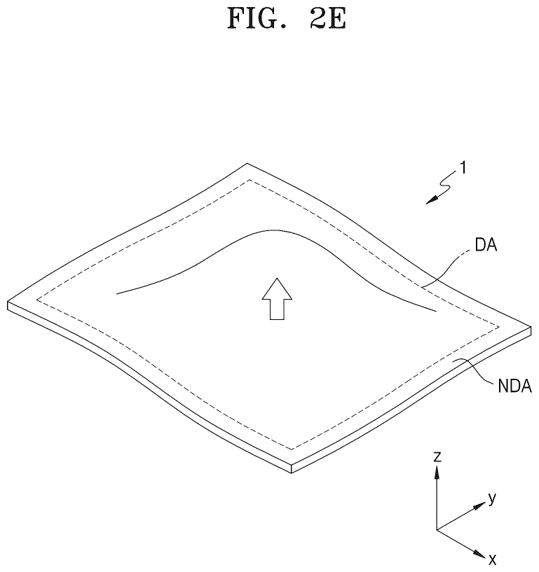

FIG. 1 is a schematic perspective view of a display apparatus 1 according to one or more embodiments, and FIGS. 2A and 2B are perspective views of the display apparatus 1 of FIG. 1 stretched in a first direction. FIG. 2C is a perspective view of the display apparatus 1 of FIG. 1 stretched in a second direction, FIG. 2D is a perspective view of the display apparatus 1 of FIG. 1 stretched in the first direction and the second direction, and FIG. 2E is a perspective view of the display apparatus 1 of FIG. 1 stretched in a third direction.

Referring to FIG. 1, the display apparatus 1 may include a display area DA and a non-display area NDA. The display area DA may include a plurality of pixels. The display apparatus 1 may provide a corresponding image by using light emitted from the plurality of pixels. The non-display area NDA may be arranged outside the display area DA. The non-display area NDA may be an area in which pixels are not arranged, and the non-display area NDA may entirely surround the display area DA (e.g., in plan view).

The display apparatus 1 may be stretched or shrunk in various directions. The display apparatus 1 may be stretched in an x direction and/or a −x direction by an external force applied by an external object or a user. According to one or more embodiments, as illustrated in FIGS. 2A and 2B, the display area DA and/or the non-display area NDA of the display apparatus 1 may be stretched in the x direction and/or the −x direction. For example, the display area DA and/or the non-display area NDA of the display apparatus 1 may be stretched in the x direction and the −x direction, as illustrated in FIG. 2A, or may be stretched in the x direction with a side of the display apparatus 1 fixed, as illustrated in FIG. 2B.

The display apparatus 1 may be stretched in a y direction and/or a −y direction by an external force applied by an external object or a user. According to one or more embodiments, as illustrated in FIG. 2C, the display area DA and/or the non-display area NDA of the display apparatus 1 may be stretched in the y direction and the −y direction. According to one or more other embodiments, the display area DA and/or the non-display area NDA of the display apparatus 1 may be stretched in the y direction and the −y direction with a side of the display apparatus 1 fixed.

The display apparatus 1 may be stretched in a plurality of directions, for example, the x direction, the −x direction, the y direction, and/or the −y direction, by an external force applied by an external object or a part of a human body. As illustrated in FIG. 2D, the display area DA and/or the non-display area NDA of the display apparatus 1 may be stretched in the x direction, the −x direction, the y direction, and the −y direction.

The display apparatus 1 may be stretched in a z direction or a −z direction by an external force applied by an external object or a part of a human body. According to one or more embodiments, FIG. 2E illustrates that a portion of the display apparatus 1 (e.g., a region of the display area DA) may protrude in the z direction. According to one or more other embodiments, a portion of the display apparatus 1 (e.g., a region of the display area DA) may protrude in the −z direction (or may be recessed in the z direction).

FIGS. 2A to 2E illustrate that the display apparatus 1 may be stretched in the x direction, the −x direction, the y direction, the −y direction, the z direction, and/or the −z direction. However, the disclosure is not limited thereto. According to one or more other embodiments, the display apparatus 1 may be variously deformed to have amorphous shapes, such as a shape that is bent or twisted with respect to two or more axes, etc.

According to one or more embodiments, the display apparatus 1 may include a curved display apparatus in which a portion of the display area DA is curved by a pre-set curvature. According to one or more other embodiments, the display apparatus 1 may include a foldable display apparatus, which may be folded or unfolded with respect to a folding axis extending in a direction. According to one or more other embodiments, the display apparatus 1 may include a rollable display apparatus which may be rolled with respect to a virtual axis.

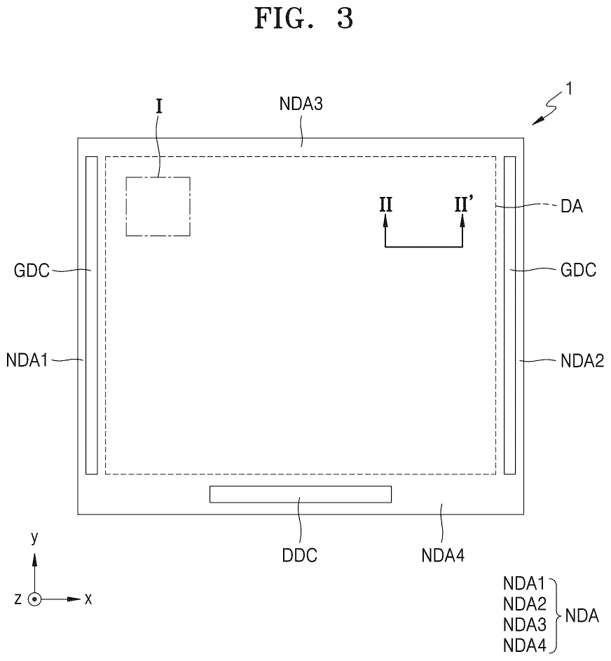

FIG. 3 is a schematic plan view of the display apparatus 1 according to one or more embodiments.

A plurality of pixels may be arranged in the display area DA of the display apparatus 1. Each pixel may emit a different color of light. According to one or more embodiments, the pixels may emit red light, green light, and blue light, respectively. According to one or more other embodiments, the pixels may emit red light, green light, blue light, and white light, respectively.

A light-emitting diode corresponding to each pixel may be arranged in the display area DA. In the non-display area NDA around the display area DA, circuits configured to provide electrical signals to the light-emitting diodes arranged in the display area DA and transistors electrically connected to the light-emitting diodes may be arranged. A gate-driving circuit GDC may be arranged in each of a first non-display area NDA1 and a second non-display area NDA2 that are respectively arranged at both sides of the display area DA. The gate-driving circuit GDC may include drivers respectively configured to provide electrical signals to gate electrodes of the transistors electrically connected to the light-emitting diodes. FIG. 3 illustrates that the gate-driving circuit GDC may be arranged in each of the first non-display area NDA1 and the second non-display area NDA2. However, the disclosure is not limited thereto. According to one or more other embodiments, the gate-driving circuit GDC may be arranged in any one of the first non-display area NDA1 and the second non-display area NDA2.

A data-driving circuit DDC may be arranged in a third non-display area NDA3 and/or a fourth non-display area NDA4, which connect the first non-display area NDA1 to the second non-display area NDA2. According to one or more embodiments, FIG. 3 illustrates that the data-driving circuit DDC may be arranged in the fourth non-display area NDA4. According to one or more other embodiments, the data-driving circuit DDC may be arranged in each of the third non-display area NDA3 and the fourth non-display area NDA4.

FIG. 3 illustrates that the data-driving circuit DDC may be arranged in the fourth non-display area NDA4 of the display apparatus 1. However, the disclosure is not limited thereto. According to one or more other embodiments, the display apparatus 1 may further include a flexible circuit board electrically connected thereto through a terminal portion arranged in the fourth non-display area NDA4, and the data-driving circuit DDC may be arranged on the flexible circuit board described above.

According to one or more embodiments, an elongation rate of the non-display area NDA may be the same as, or less than, an elongation rate of the display area DA. According to one or more embodiments, the elongation rate of the non-display area NDA may be different for each region of the non-display area NDA. For example, the first non-display area NDA1, the second non-display area NDA2, and the third non-display area NDA3 may have substantially the same elongation rate, while the fourth non-display area NDA4 may have a less elongation rate than each of the first non-display area NDA1, the second non-display area NDA2, and the third non-display area NDA3.

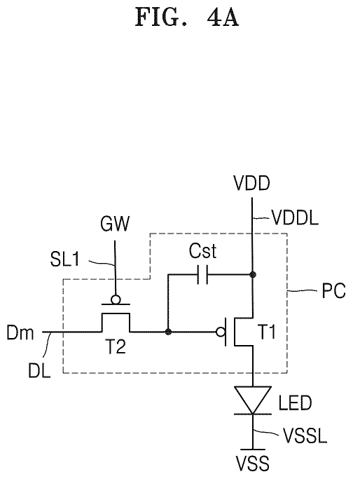

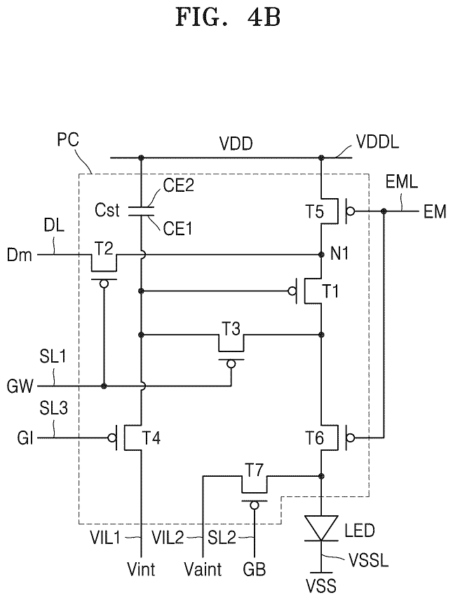

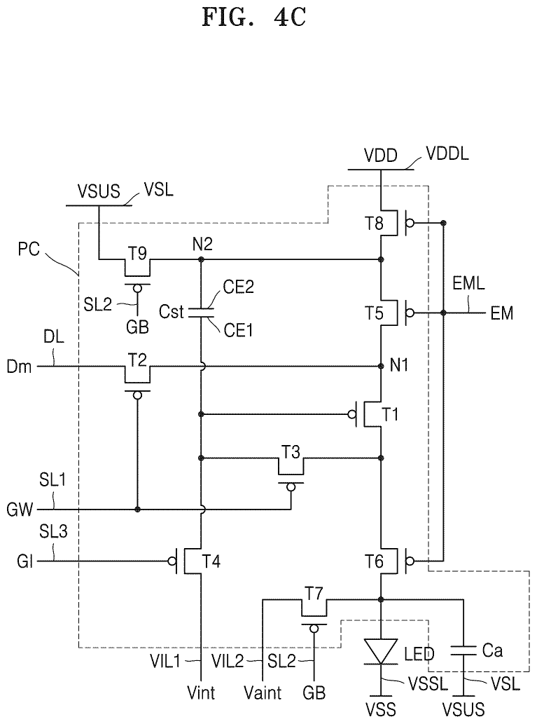

FIGS. 4A to 4C are respectively equivalent circuit diagrams of a pixel of a display apparatus according to one or more embodiments.

Referring to FIG. 4A, a light-emitting diode LED corresponding to a pixel may be electrically connected to a pixel-driving circuit PC, and the pixel-driving circuit PC may include a first transistor T1, a second transistor T2, and a storage capacitor Cst. The pixel-driving circuit PC may be electrically connected to signal lines and voltage lines. The signal lines may include a gate line, such as a first scan line SL1, and a data line DL, and the voltage lines may include a first voltage line (a driving power voltage line) VDDL.

The second transistor T2 may be electrically connected to the first scan line SL1 and the data line DL. The first scan line SL1 may be configured to provide a first scan signal GW to a gate electrode of the second transistor T2. The second transistor T2 may include a switching transistor turned on or off in response to the first scan signal SW input from the first scan line SL1. The second transistor T2 may be electrically connected to the first transistor T1, and may be configured to transmit a data signal Dm input from the data line DL to the first transistor T1.

The storage capacitor Cst may be electrically connected to the second transistor T2 and the first voltage line VDDL, and may be configured to store a voltage corresponding to the difference between a voltage transmitted from the second transistor T2 and a first power voltage VDD supplied by the first voltage line VDDL.

The first transistor T1 may include a driving transistor, and may be configured to control a driving current flowing through the light-emitting diode LED. The first transistor T1 may be connected to the first voltage line VDDL and the storage capacitor Cst. The first transistor T1 may be configured to control a driving current flowing from the first voltage line VDDL to the light-emitting diode LED according to a value of the voltage stored in the storage capacitor Cst. The light-emitting diode LED may emit light having a corresponding brightness according to the driving current. A first electrode (an anode) of the light-emitting diode LED may be electrically connected to the first transistor T1, and a second electrode (a cathode) of the light-emitting diode LED may be electrically connected to a second voltage line VSSL configured to supply a second power voltage (a common power voltage) VSS.

FIG. 4A illustrates that the pixel-driving circuit PC may include two transistors and one storage capacitor. However, according to one or more other embodiments, the pixel-driving circuit PC may include three or more transistors.

Referring to FIG. 4B, the pixel-driving circuit PC may include a first transistor T1, a second transistor T2, a third transistor T3, a fourth transistor T4, a fifth transistor T5, a sixth transistor T6, a seventh transistor T7, and a storage capacitor Cst. The pixel-driving circuit PC may be electrically connected to signal lines and voltage lines. The signal lines may include gate lines, such as a first scan line SL1, a second scan line SL2, a third scan line SL3, and an emission control line EML, and a data line DL. The voltage lines may include first and second initialization voltage lines VIL1 and VIL2 and a first voltage line VDDL.

The first voltage line VDDL may be configured to transmit a first power voltage VDD to the first transistor T1. The first initialization voltage line VIL1 may be configured to transmit a first initialization voltage Vint for initializing the first transistor T1 to the pixel-driving circuit PC. The second initialization voltage line VIL2 may be configured to transmit a second initialization voltage Vaint for initializing a first electrode of the light-emitting diode LED to the pixel-driving circuit PC.

The first transistor T1 may be electrically connected to the first voltage line VDDL through the fifth transistor T5, and may be electrically connected to the light-emitting diode LED through the sixth transistor T6. The first transistor T1 may function as a driving transistor, and may be configured to receive a data signal Dm, and to transmit a driving current to the light-emitting diode LED according to a switching operation of the second transistor T2.

The second to seventh transistors T2 to T7 may include switching transistors turned on or off according to a gate-source voltage or a gate voltage.

The second transistor T2 may include a data write transistor, and may be electrically connected to the first scan line SL1 and the data line DL. The second transistor T2 may be electrically connected to the first voltage line VDDL through the fifth transistor T5. The second transistor T2 may be turned on according to a first scan signal GW received through the first scan line SL1, and may be configured to perform a switching operation of transmitting the data signal Dm transmitted through the data line DL to a first node N1.

The third transistor T3 may be electrically connected to the first scan line SL1, and may be electrically connected to the light-emitting diode LED through the sixth transistor T6. The third transistor T3 may be turned on according to the first scan signal GW received through the first scan line SL1, and may diode-connect the first transistor T1.

The fourth transistor T4 may include a first initialization transistor, and may be electrically connected to the third scan line SL3 and to the first initialization voltage line VIL1. The fourth transistor T4 may be turned on according to a third scan signal GI received through the third scan line SL3, and may be configured to transmit the first initialization voltage Vint from the first initialization voltage line VIL1 to a gate electrode of the first transistor T1 to initialize a voltage of the gate electrode of the first transistor T1. The third scan signal GI may correspond to a first scan signal of a different pixel-driving circuit arranged in a previous row of the corresponding pixel-driving circuit PC.

The fifth transistor T5 may include an operation control transistor, and the sixth transistor T6 may include an emission control transistor. The fifth transistor T5 and the sixth transistor T6 may be electrically connected to the emission control line EML, and may be concurrently or substantially simultaneously turned on according to an emission control signal EM received through the emission control line EML to form a current path through which a driving current may flow from the first voltage line VDDL in a direction toward the light-emitting diode LED.

The seventh transistor T7 may include a second initialization transistor, and may be electrically connected to the second scan line SL2, the second initialization voltage line VIL2, and the sixth transistor T6. The seventh transistor T7 may be turned on according to a second scan signal GB received through the second scan line SL2, and may be configured to transmit the second initialization voltage Vaint from the second initialization voltage line VIL2 to the first electrode of the light-emitting diode LED to initialize the first electrode of the light-emitting diode LED.

The storage capacitor Cst may include a first capacitor electrode CE1 and a second capacitor electrode CE2. The first capacitor electrode CE1 may be electrically connected to the gate electrode of the first transistor T1, and the second capacitor electrode CE2 may be electrically connected to the first voltage line VDDL. The storage capacitor Cst may be configured to store and sustain a voltage corresponding to the difference between a voltage of the first voltage line VDDL and a voltage of the gate electrode of the first transistor T1, so as to sustain a voltage applied to the gate electrode of the first transistor T1.

Referring to FIG. 4C, the pixel-driving circuit PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca.

The pixel-driving circuit PC may be electrically connected to signal lines and voltage lines. The signal lines may include gate lines, such as a first scan line SL1, a second scan line SL2, a third scan line SL3, and an emission control line EML, and also may include a data line DL. The voltage lines may include first and second initialization voltage lines VIL1 and VIL2, a sustaining voltage line VSL, and a first voltage line VDDL.

The first voltage line VDDL may be configured to transmit a first power voltage VDD to the first transistor T1. The first initialization voltage line VIL1 may be configured to transmit a first initialization voltage Vint for initializing the first transistor T1 to the pixel-driving circuit PC. The second initialization voltage line VIL2 may be configured to transmit a second initialization voltage Vaint for initializing a first electrode of the light-emitting diode LED to the pixel-driving circuit PC. The sustaining voltage line VSL may be configured to provide a sustaining voltage VSUS to a second node N2 (e.g., a second capacitor electrode CE2 of the storage capacitor Cst) in an initialization section and a data write section.

The first transistor T1 may be electrically connected to the first voltage line VDDL through the fifth transistor T5, and the eighth transistor T8 and may be electrically connected to the light-emitting diode LED through the sixth transistor T6. The first transistor T1 may function as a driving transistor, and may be configured to receive a data signal Dm, and to transmit a driving current to the light-emitting diode LED according to a switching operation of the second transistor T2.

The second to ninth transistors T2 to T9 may include switching transistors turned on or off according to a gate-source voltage or a gate voltage.

The second transistor T2 may be electrically connected to the first scan line SL1 and the data line DL, and may be electrically connected to the first voltage line VDDL through the fifth transistor T5 and the eighth transistor T8. The second transistor T2 may be turned on according to a first scan signal GW received through the first scan line SL1, and may be configured to perform a switching operation of transmitting the data signal Dm transmitted through the data line DL to a first node N1.

The third transistor T3 may be electrically connected to the first scan line SL1, and may be electrically connected to the light-emitting diode LED through the sixth transistor T6. The third transistor T3 may be turned on according to the first scan signal GW received through the first scan line SL1, and may be configured to diode-connect the first transistor T1 to compensate for a threshold voltage of the first transistor T1.

The fourth transistor T4 may be electrically connected to the third scan line SL3 and to the first initialization voltage line VIL1, may be turned on according to a third scan signal GI received through the third scan line SL3, and may be configured to transmit the first initialization voltage Vint from the first initialization voltage line VIL1 to a gate electrode of the first transistor T1 to initialize a voltage of the gate electrode of the first transistor T1. The third scan signal GI may correspond to a first scan signal of a different pixel-driving circuit arranged in a previous row of the corresponding pixel-driving circuit PC.

The fifth transistor T5, the sixth transistor T6, and the eighth transistor T8 may be electrically connected to the emission control line EML, and may be concurrently or substantially simultaneously turned on according to an emission control signal EM received through the emission control line EML to form a current path through which a driving current may flow from the first voltage line VDDL in a direction toward the light-emitting diode LED.

The seventh transistor T7 may include a second initialization transistor, and may be electrically connected to the second scan line SL2, to the second initialization voltage line VIL2, and to the sixth transistor T6. The seventh transistor T7 may be turned on according to a second scan signal GB received through the second scan line SL2, and may be configured to transmit the second initialization voltage Vaint from the second initialization voltage line VIL2 to the first electrode of the light-emitting diode LED to initialize the first electrode of the light-emitting diode LED.

The ninth transistor T9 may be electrically connected to the second scan line SL2, to the second capacitor electrode CE2 of the storage capacitor Cst, and to the sustaining voltage line VSL. The ninth transistor T9 may be turned on according to the second scan signal GB received through the second scan line SL2, and may be configured to transmit the sustaining voltage VSUS to a second node N2 (e.g., to the second capacitor electrode CE2 of the storage capacitor Cst) in an initialization section and a data write section.

Each of the eighth transistor T8 and the ninth transistor T9 may be electrically connected to the second node N2 (e.g., to the second capacitor electrode CE2 of the storage capacitor Cst). According to one or more embodiments, in the initialization section and the data write section, the eighth transistor T8 may be turned off, and the ninth transistor T9 may be turned on, and in the emission section, the eighth transistor T8 may be turned on, and the ninth transistor T9 may be turned off. The sustaining voltage VSUS may be transmitted to the second node N2 in the initialization section and the data write section, and thus, the uniformity of the brightness (for example, the long range uniformity (LRU)) of the display apparatus according to a voltage drop of the first voltage line VDDL may be improved.

The storage capacitor Cst may include a first capacitor electrode CE1 and the second capacitor electrode CE2. The first capacitor electrode CE1 may be electrically connected to the gate electrode of the first transistor T1, and the second capacitor electrode CE2 may be electrically connected to the eighth transistor T8 and to the ninth transistor T9.

The auxiliary capacitor Ca may be electrically connected to the sixth transistor T6, to the sustaining voltage line VSL, and to the first electrode of the light-emitting diode LED. The auxiliary capacitor Ca may be configured to store and sustain a voltage corresponding to the difference between voltages of the first electrode of the light-emitting diode LED and the sustaining voltage line VSL, while the seventh transistor T7 and the ninth transistor T9 are being turned on, and thus, the auxiliary capacitor Ca may reduce or prevent an increase in black brightness if the sixth transistor T6 is turned off.

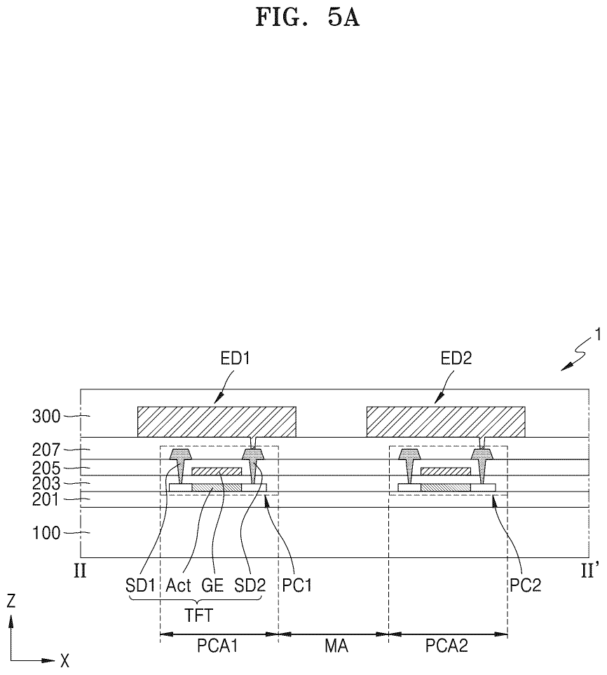

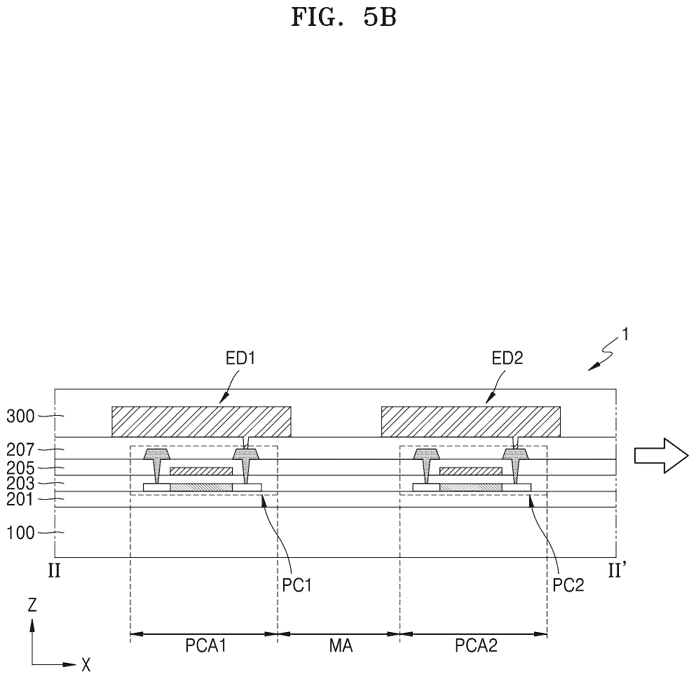

FIG. 5A is a schematic cross-sectional view of a portion of a display apparatus according to one or more embodiments, and FIG. 5B is a schematic cross-sectional view of the portion of the display apparatus illustrated in FIG. 5A stretched in a first direction. FIGS. 5A and 5B may respectively be the cross-sectional views of the display apparatus 1 of FIG. 3 taken along the line II-II′.

Referring to FIGS. 5A and 5B, the display apparatus 1 may include a substrate 100, and a first pixel and a second pixel arranged on the substrate 100. The first pixel may include a first pixel-driving circuit PC1, and a first light-emitting diode ED1 electrically connected to the first pixel-driving circuit PC1. The second pixel may include a second pixel-driving circuit PC2, and a second light-emitting diode ED2 electrically connected to the second pixel-driving circuit PC2.

The first pixel-driving circuit PC1 may be arranged in a first device area PCA1, and the second pixel-driving circuit PC2 may be arranged in a second device area PCA2. A middle area MA may be arranged between the first device area PCA1 and the second device area PCA2. Lines, such as voltage lines, gate lines, and data lines, may be arranged in the middle area MA.

The substrate 100 may include a stretchable substrate, which may be stretched or shrunk in a corresponding direction. The substrate 100 may include an insulating material, such as glass, quartz, and polymer resins. The substrate 100 may include an elastomer. The elastomer may include an organic elastomer, an organic and inorganic elastomer, or a combination thereof. For example, the substrate 100 may include a silicon-based elastomer, such as polydimethylsiloxane, etc., a styrene-based elastomer, an olefin-based elastomer, polyurethane, or a mixture thereof. The substrate 100 may have a single-layered or multi-layered structure.

A first insulating layer 201 may be located on the substrate 100. The first insulating layer 201 may prevent or reduce the penetration of impurities from the substrate 100, and may provide a flat base surface to the first pixel-driving circuit PC1 and the second pixel-driving circuit PC2 located on the first insulating layer 201. According to one or more embodiments, the first insulating layer 201 may include an organic insulating material, an inorganic insulating material, or an organic and inorganic insulating material, and may have a single-layered or multi-layered structure. According to one or more other embodiments, the first insulating layer 201 may include an insulating elastomer.

The first pixel-driving circuit PC1 and the second pixel-driving circuit PC2 may be located on the first insulating layer 201. Each of the first pixel-driving circuit PC1 and the second pixel-driving circuit PC2 may include a thin-film transistor TFT. The thin-film transistor TFT may include a semiconductor layer Act, a gate electrode GE, a first source-drain electrode SD1, and a second source-drain electrode SD2.

The semiconductor layer Act of the thin-film transistor TFT may be located on the first insulating layer 201. The semiconductor layer Act may include a channel area, and impurities areas arranged at respective sides of the channel area. Any one of the impurities areas arranged at the both sides of the channel area may correspond to a source area, and the other may correspond to a drain area.

The semiconductor layer Act may include a semiconductor material. According to one or more embodiments, the semiconductor material may include a silicon-based semiconductor material or an oxide-based semiconductor material.

The silicon-based semiconductor material may include amorphous silicon or polysilicon. The oxide-based semiconductor material may include oxide of at least one material selected from the group consisting of In, Ga, Sn, Zr, V, Hf, Cd, Ge, Cr, Ti, Al, Cs, Ce, and/or Zn. The oxide-based semiconductor material may include In—Ga—Zn—O (IGZO), In—Sn—Zn—O (ITZO), or In—Ga—Sn—Zn—O (IGTZO), which is ZnO containing metal, such as In, Ga, and/or Sn.

According to one or more other embodiments, the semiconductor layer Act may include a stretchable semiconductor material. Here, the stretchable semiconductor material may maintain the semiconductor characteristics even if the semiconductor layer Act is stretched and deformed. For example, the stretchable semiconductor material may include an organic semiconductor material or a carbon nanotube. The organic semiconductor material may include a semiconductor low-molecular weight material or a semiconductor high-molecular weight material. For example, the organic semiconductor material may include pentacene, tetracene, anthracene, naphthalene, flullerene, alpha-6-thiophene, alpha-4-thiophene, oligo thiophene, perylene or its derivatives, rubrene or its derivatives, coronene or its derivatives, perylenetetra carboxylic diimide or its derivatives, perylenetetra carboxylic dianhydride or its derivatives, polythiophene or its derivatives, polyparaphenylenevinylene or its derivatives, polyparaphenylene or its derivatives, polyflullerene or its derivatives, polythiophenevinylene or its derivatives, a polythiophene-heterocylic aromatic copolymer or its derivatives, oligoacene of naphthalene or their derivatives, naphthalene tetra carboxylic acid diimide or its derivatives, oligothiophene of alpha-5-thiophene or their derivatives, metallic or non-metallic phthalocyanines or their derivatives, pyromellitic dianhydride or its derivatives, pyromellitic diimide or its derivatives, polyalkylthiophene, polythienylenevinylene, an alkylfluorene unit, an alkylthiophene copolymer, diketopyrrolopyrrole or its derivatives, etc. However, these materials are examples, and other organic semiconductor materials may be included in the semiconductor layer Act.

According to one or more embodiments, the semiconductor layer Act may include a composite layer including a carbon nanotube, an organic semiconductor material, etc. distributed in a polymer resin. For example, the semiconductor layer Act may include a composite layer including diketopyrrolopyrrole-based semiconductor material and a styrene-ethylene-buthylene-styrene elastomer, a composite layer including a poly 3-hexyl thiophene semiconductor material and a styrene-ethylene-buthylene-styrene elastomer, or a composite layer including a poly 3-hexyl thiophene nanofiber and polydimethylsiloxane. The semiconductor layer Act may be formed by screen printing, printing, spin coating, deep coating, or ink injection, but is not limited thereto.

A second insulating layer 203 may be located on the semiconductor layer Act. The second insulating layer 203 may include an insulating material and may include a single-layered or multi-layered structure. The second insulating layer 203 may include an organic insulating material, an inorganic insulating material, or an organic and inorganic insulating material and may have a single-layered or multi-layered structure. According to one or more embodiments, the second insulating layer 203 may include an insulating elastomer.

As illustrated in FIG. 5B, the semiconductor layer Act may be stretched, shrunk, or curved in a corresponding direction together with a peripheral area. The semiconductor material included in the semiconductor layer Act may be relatively less stretchable than a peripheral area. According to one or more embodiments, to reduce or prevent the occurrence of cracks, etc. in the semiconductor layer Act, elastomer layers may be arranged to face each other with the semiconductor layer Act therebetween. For example, the first insulating layer 201 in contact with a lower surface of the semiconductor layer Act and the second insulating layer 203 in contact with an upper surface of the semiconductor layer Act may include an insulating elastomer. The first insulating layer 201 and the second insulating layer 203 may include a silicon-based elastomer, a styrene-based elastomer, an olefin-based elastomer, polyurethane, or a mixture thereof. The first insulating layer 201 and the second insulating layer 203 may include polyurethane, polydimethylsiloxane, a styrene-ethylene-buthylene-styrene copolymer, or a mixture thereof. The semiconductor layer Act may be located between the first insulating layer 201 and the second insulating layer 203 as a sandwich structure, and thus, the electrical characteristics of the thin-film transistor TFT may be maintained constant even if the semiconductor layer Act includes a silicon-based semiconductor material or an oxide-based semiconductor material having a low stretchable characteristic. According to one or more other embodiments, only one of the first insulating layer 201 and the second insulating layer 203, which are directly in contact with the semiconductor layer Act, may include an elastomer.

The gate electrode GE may be located on the second insulating layer 203. The gate electrode GE may include a conductive material. The gate electrode GE may include a metal material, such as Mo, Al, Cu, Ti, etc. According to one or more embodiments, the gate electrode GE may include a stretchable conductive material. For example, the gate electrode GE may include a conductive composite in which a metal nanostructure, etc. are distributed in a polymer resin. The conductive composite may include an elastomer, and may further include an additive, such as a carbon nanotube, a carbon fiber, graphene, and/or graphene oxide, to have increased conductivity. According to one or more other embodiments, the gate electrode GE may include a liquid metal material, such as a eutectic gallium-indium alloy. The gate electrode GE may have a single-layered or multi-layered structure.

According to one or more other embodiments, the thin-film transistor TFT may have a bottom-gate structure. For example, the gate electrode GE may be located below the semiconductor layer Act with the first insulating layer 201 therebetween. According to one or more other embodiments, the thin-film transistor TFT may have a dual-gate structure including both of a top gate located on the semiconductor layer Act and a bottom gate located below the semiconductor layer Act.

A third insulating layer 205 may be located on the gate electrode GE. The third insulating layer 205 may include an organic insulating material, an inorganic insulating material, or an organic and inorganic insulating material and may have a single-layered or multi-layered structure.

The first source-drain electrode SD1 and the second source-drain electrode SD2 may be located on the third insulating layer 205. Each of the first source-drain electrode SD1 and the second source-drain electrode SD2 may be electrically connected to the semiconductor layer Act through a contact hole passing through the second insulating layer 203 and the third insulating layer 205. According to one or more embodiments, at least one of the first source-drain electrode SD1 or the second source-drain electrode SD2 may be omitted, and the thin-film transistor TFT may be connected to an adjacent thin-film transistor through a source area or a drain area. The first source-drain electrode SD1 and the second source-drain electrode SD2 may include a conductive material, such as a metal material, a conductive composite, or a liquid metal material. The first source-drain electrode SD1 and the second source-drain electrode SD2 may have a single-layered or multi-layered structure.

A fourth insulating layer 207 may be located on the first source-drain electrode SD1 and the second source-drain electrode SD2. The fourth insulating layer 207 may provide a flat base surface to the first light-emitting diode ED1 and to the second light-emitting diode ED2 located thereabove. The fourth insulating layer 207 may include an organic insulating material and may have a single-layered or multi-layered structure.

The first light-emitting diode ED1 and the second light-emitting diode ED2 may be located on the fourth insulating layer 207. The first light-emitting diode ED1 may be electrically connected to the first pixel-driving circuit PC1 through a contact hole passing through the fourth insulating layer 207. Likewise, the second light-emitting diode ED2 may be electrically connected to the second pixel-driving circuit PC2 through a contact hole passing through the fourth insulating layer 207.

An encapsulation layer 300 may selectively cover the first light-emitting diode ED1 and the second light-emitting diode ED2. The encapsulation layer 300 may reduce or prevent the penetration of impurities, such as moisture, etc. into the first light-emitting diode ED1 and the second light-emitting diode ED2. The encapsulation layer 300 may include a polymer resin and an elastomer.

The display apparatus 1 may be stretched or shrunk in a corresponding direction. With this aspect, FIG. 5B illustrates that the display apparatus 1 may be stretched in an x direction.

As the display apparatus 1 is stretched in the x direction, each of the first device area PCA1, the second device area PCA2, and the middle area MA may be stretched in the x direction. According to one or more embodiments, an elongation rate of each of the first device area PCA1 and the second device area PCA2 may be the same as, or less than, an elongation rate of the middle area MA.

The layers included in the first pixel-driving circuit PC1 and the second pixel-driving circuit PC2 may be stretchable, and may be stretched together if the display apparatus 1 is stretched. Each of the first pixel-driving circuit PC1 and the second pixel-driving circuit PC2 may include a stretchable thin-film transistor TFT. The stretchable thin-film transistor TFT may maintain the electrical characteristics of the thin-film transistor TFT constant, even if the display apparatus 1 is stretched or shrunk.

For example, the semiconductor layer Act of the thin-film transistor TFT may include a stretchable semiconductor material. Alternatively, the semiconductor layer Act may have a sandwich structure in which the semiconductor layer Act is located between elastomer layers. The gate electrode GE of the thin-film transistor TFT may include a stretchable conductive material.

When the channel area of the thin-film transistor TFT is stretched and deformed, the channel area may have a shape to reduce the change of the electrical characteristics of the thin-film transistor TFT, which may occur due to the change in channel length and channel width. For example, the channel area of the thin-film transistor TFT may have a line symmetrical shape having a symmetric axis extending in a direction oblique by about 45° with respect to the stretching direction (for example, the x direction).

According to a comparative example, in a display apparatus of the related art, layers included in a pixel-driving circuit may not be stretched. In this display apparatus, so that stress due to stretching of the display apparatus is not transmitted to the pixel-driving circuit, structures for the stretching, such as an opening, a concavo-convex portion, a wrinkle, etc., may have to be formed in a middle area between device areas in which the pixel-driving circuits are arranged.

However, in the display apparatus 1 according to embodiments, the layers included in the first pixel-driving circuit PC1 and the second pixel-driving circuit PC2 may be stretchable, and thus, the structure for the stretching may be omitted between the first pixel-driving circuit PC1 and the second pixel-driving circuit PC2. Thus, not only a manufacturing process for the display apparatus 1 may be simplified to reduce the cost and the defective rate, but also pixels may be arranged in an increased density. Thus, the display apparatus 1 with high resolution may be provided.

According to one or more embodiments, as illustrated in FIG. 5B, the first light-emitting diode ED1 and the second light-emitting diode ED2 may be stretched or shrunk together if the display apparatus 1 is stretched or shrunk. According to one or more embodiments, the first light-emitting diode ED1 and the second light-emitting diode ED2 may have an elongation rate that is less than that of peripheral areas, or may not be stretched.

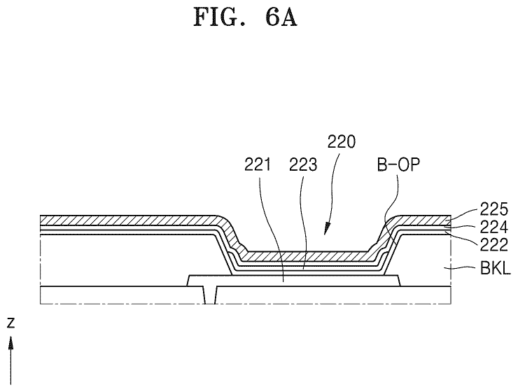

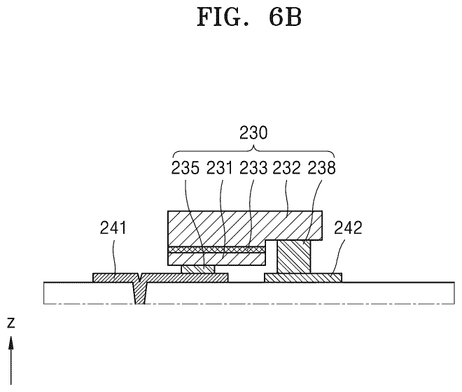

FIGS. 6A and 6B are respectively schematic cross-sectional views of a light-emitting diode of a display apparatus according to one or more embodiments.

Referring to FIG. 6A, the light-emitting diode according to one or more embodiments may include an organic light-emitting diode 220 including an organic material. The organic light-emitting diode 220 may include a first electrode 221 located on an insulating layer (for example, the fourth insulating layer 207), a second electrode 225 facing the first electrode 221, and an emission layer 223 located between the first electrode 221 and the second electrode 225. A first functional layer 222 may be located between the first electrode 221 and the emission layer 223, and a second functional layer 224 may be located between the emission layer 223 and the second electrode 225.

An edge of the first electrode 221 may be covered by a bank layer BKL including an insulating material. The bank layer BKL may include an opening B-OP overlapping a central portion of the first electrode 221.

The first electrode 221 may include conductive oxide, such as indium tin oxide (ITO), indium zinc oxide (IZO), zinc oxide (ZnO), indium oxide (In₂O₃), indium gallium oxide (IGO), or aluminum zinc oxide (AZO). According to one or more other embodiments, the first electrode 221 may include a reflective layer including Ag, Mg, Al, Pt, Pd, Au, Ni, Nd, Ir, Cr, or a compound thereof. According to one or more other embodiments, the first electrode 221 may further include a layer including ITO, IZO, ZnO, AZO, or In₂O₃ above/below the reflective layer described above.

The emission layer 223 may include a high molecular-weight or a low molecular-weight organic material for emitting light of a corresponding color. The first functional layer 221 may include a hole transport layer (HTL) and/or a hole injection layer (HIL). The second functional layer 224 may include an electron transport layer and/or an electron injection layer.

The second electrode 225 may include a conductive material having a low work function. For example, the second electrode 225 may include a transparent (semi-transparent) layer including Ag, Mg, Al, Pt, Pd, Au, Ni, Nd, Ir, Cr, Li, Ca, or an alloy thereof. Alternatively, the second electrode 225 may further include a layer, such as ITO, IZO, ZnO, AZO, or In₂O₃, on the transparent (semi-transparent) layer including the material described above.

Referring to FIG. 6B, the light-emitting diode according to one or more embodiments may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be electrically connected to a first electrode pad 241 and a second electrode pad 242, respectively, which are arranged on the same layer.

According to one or more embodiments, the first semiconductor layer 231 may include a p-type semiconductor layer. The p-type semiconductor layer may include a semiconductor material having a composition of InₓAl_{y}Ga_{1-x-y}N (0≤x≤1, 0≤y≤1, and 0≤x+y≤1), for example, a material selected from among GaN, AlN, AlGaN, InGaN, InN, InAlGaN, AlInN, and/or the like, and may be doped with a p-type dopant, such as Mg, Zn, Ca, Sr, Ba, and/or the like.

The second semiconductor layer 232 may include, for example, an n-type semiconductor layer. The n-type semiconductor layer may include a semiconductor material having a composition of InₓAl_{y}Ga_{1-x-y}N (0≤x≤1, 0≤y≤1, and 0≤x+y≤1), for example, a material selected from among GaN, AlN, AlGaN, InGaN, InN, InAlGaN, AlInN, and/or the like, and may be doped with an n-type dopant, such as Si, Ge, Sn, and/or the like.

The intermediate layer 233 may be where electrons and holes reunite, and when the electrons and the holes reunite, transition to a reduced energy level may be performed to generate light having a wavelength corresponding to the reduced energy level. The intermediate layer 233 may include, for example, a semiconductor material having a composition of InₓAl_{y}Ga_{1-x-y}N (0≤x≤1, 0≤y≤1, and 0≤x+y≤1), and may be formed as a single quantum well structure or a multi-quantum well (MQW) structure. Also, the intermediate layer 233 may include a quantum wire structure or a quantum dot structure.

It is described with reference to FIG. 6B that the first semiconductor layer 231 may include the p-type semiconductor layer, and the second semiconductor layer 232 may include the n-type semiconductor layer. However, the disclosure is not limited thereto. According to one or more other embodiments, the first semiconductor layer 231 may include the n-type semiconductor layer and the second semiconductor layer 232 may include the p-type semiconductor layer.

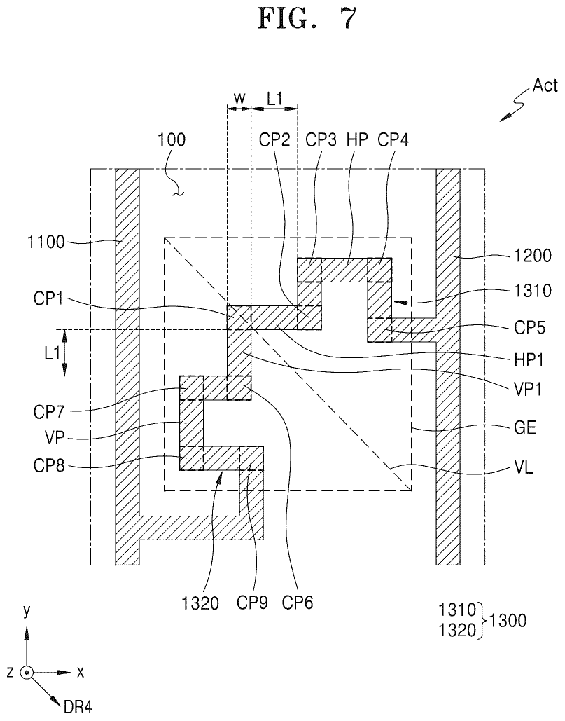

FIG. 7 is a schematic plan view of a semiconductor layer Act of a display apparatus according to one or more embodiments.

The pixel-driving circuits PC (see FIG. 4A) included in the display apparatus may be arranged to form a matrix in a first direction (e.g., a row and x direction) and in a second direction (e.g., a column and y direction) in the display area DA (see FIG. 1). As described with reference to FIGS. 4A to 4C, each pixel-driving circuit PC may include a driving transistor (e.g., the first transistor T1) configured to control a driving current flowing through the light-emitting diode LED, and at least one switching transistor (for example, the second transistor T2) electrically connected to the driving transistor.

The semiconductor layer Act may be located on the substrate 100. According to one or more embodiments, the semiconductor layer Act may include a driving channel area 1300 overlapping a gate electrode of the driving transistor, and a switching channel area overlapping a gate electrode of the switching transistor. To increase a driving range of the driving transistor, a channel length of the driving channel area 1300 may be provided to be greater than a channel length of the switching channel area.

FIG. 7 schematically illustrates a plan view of the semiconductor layer Act in a third direction (e.g., a thickness and z direction), based on the driving channel area 1300 of the driving transistor and its peripheral areas, that is, a first area 1100 and a second area 1200. In FIG. 7, a gate electrode GE of the driving transistor, which is located on a different layer from the semiconductor layer Act, is projected.

Referring to FIG. 7, the semiconductor layer Act may include the first area 1100, the second area 1200, and the driving channel area 1300. The first area 1100 and the second area 1200 may be conductive areas that are doped with impurities, etc., and any one of the first area 1100 and the second area 1200 may be a source area of the driving transistor, and the other may be a drain area of the driving transistor.

Each of the first area 1100 and the second area 1200 may extend in a second direction (e.g., a y direction). According to one or more embodiments, the first area 1100 and/or the second area 1200 may be connected to the switching channel area of the switching transistor. The first area 1100 and the second area 1200 may be apart from each other in the first direction (e.g., an x-axis direction) and the driving channel area 1300 may be arranged between the first area 1100 and the second area 1200.

The gate electrode GE may be located above and/or below the semiconductor layer Act. The driving channel area 1300 of the semiconductor layer Act may overlap the gate electrode GE in a plan view. The driving channel area 1300 may be where a channel electrically connecting the first area 1100 to the second area 1200 may be formed according to a gate-source voltage or a gate voltage. To finely control the gradient of light emitted from the light-emitting diode, the driving transistor may have an increased driving range. To increase the driving range of the driving transistor, the driving channel area 1300 may have a relatively increased channel length. To increase the channel length in a small area, the driving channel area 1300 may have a zig-zag shape in a plan view.

The driving channel area 1300 may include a first sub-area 1310 and a second sub-area 1320 forming line symmetry with respect to a virtual straight line VL (a symmetric axis) extending in a fourth direction DR4. The fourth direction DR4 may cross the first direction (the x-axis direction) and the second direction (a y-axis direction). According to one or more embodiments, the first direction (the x-axis direction) and the second direction (the y-axis direction) may be orthogonal to each other, and the fourth direction DR4 may be oblique by about 45° in a clockwise direction with respect to the first direction (the x-axis direction). According to one or more other embodiments, the fourth direction DR4 may be oblique by about 45° in a counterclockwise direction with respect to the first direction (the x-axis direction).

The driving channel area 1300 may include horizontal channel portions (first channel portions) HP extending in the first direction (the x-axis direction), vertical channel portions (second channel portions) VP extending in the second direction (the y-axis direction), and crossing portions, namely, first to ninth crossing portions CP1 to CP9, connecting the horizontal channel portions HP to the vertical channel portions VP. The horizontal channel portions HP may include a first horizontal channel portion HP1. The vertical channel portions VP may include a first vertical channel portion VP1.

The first crossing portion CP1 from among the first to ninth crossing portions CP1 to CP9 may be arranged on the virtual straight line VL. The first crossing portion CP1 may be where the first sub-area 1310 and the second sub-area 1320 are connected to each other. For example, as illustrated in FIG. 7, the horizontal channel portion HP1 of the first sub-area 1310 and the vertical channel portion VP1 of the second sub-area 1320 may be connected to each other in the first crossing portion CP1. That is, the first sub-area 1310 and the second sub-area 1320 may be connected to each other on the virtual straight line VL as a curved shape.

Each of the first sub-area 1310 and the second sub-area 1320 may include at least two crossing portions apart from the virtual straight line VL. For example, FIG. 7 illustrates that the first sub-area 1310 may include the second crossing portion CP2, the third crossing portion CP3, the fourth crossing portion CP4, and the fifth crossing portion CP5, and the second sub-area 1320 may include the sixth crossing portion CP6, the seventh crossing portion CP7, the eighth crossing portion CP8, and the ninth crossing portion CP9. The sixth to ninth crossing portions CP6 to CP9 may form line symmetry with the second to fifth crossing portions CP2 to CP5 (e.g., respectively) with respect to the virtual straight line VL.

The crossing portions adjacent to each other in the first direction (the x-axis direction) may be connected to each other by one of the horizontal channel portions HP, and the crossing portions adjacent to each other in the second direction (the y-axis direction) may be connected to each other by one of the vertical channel portions VP. For example, the first crossing portion CP1 and the second crossing portion CP2 adjacent to each other in the first direction (the x-axis direction) may be connected to each other by a first horizontal channel portion HP1, and the first crossing portion CP1 and the sixth crossing portion CP6 adjacent to each other in the second direction (the y-axis direction) may be connected to each other by a first vertical channel portion VP1. One crossing portion may connect one horizontal channel portion HP to one vertical channel portion VP. For example, the first crossing portion CP1 may connect the first horizontal channel portion HP1 to the first vertical channel portion VP1.

According to one or more embodiments, at least a portion of the driving channel area 1300 may have a stair shape in a plan view. For example, the vertical channel portions VP and the horizontal channel portions HP may be alternately arranged with the crossing portions CP therebetween, and may form the stair shape in the plan view.

According to one or more embodiments, the driving channel area 1300 may have a shape similar to inclined “Q” in a plan view. For example, the fourth crossing portion CP4 located in the middle from among the three crossing portions, namely, the third to fifth crossing portions CP3 to CP5, which are continually connected in the first sub-area 1310, may be arranged to be farther from the virtual straight line VL than the third crossing portion CP3 and the fifth crossing portion CP5. Likewise, the eighth crossing portion CP8 located in the middle from among the three crossing portions, namely, the seventh to ninth crossing portions CP7 to CP9, which are continually connected in the second sub-area 1320, may be arranged to be farther from the virtual straight line VL than the seventh crossing portion CP7 and the ninth crossing portion CP9. Accordingly, the driving channel area 1300 may have an increased channel length in a relatively small area.

The channel length of the driving channel area 1300 may be indicated as the sum of the channel length of each horizontal channel portion HP and the channel length of each vertical channel portion VP. Here, the channel length of the driving channel area 1300 may refer to the shortest distance by which a carrier moves from a source area to a drain area. Charges may move by the shortest distance, and thus, the lengths of the first to ninth crossing portions CP1 to CP9 in the first direction (the x-axis direction) or the second direction (the y-axis direction) may be disregarded.

A channel width of the driving channel area 1300 may be the same as a channel width of each horizontal channel portion HP and a channel width of each vertical channel portion VP. The channel width of the horizontal channel portion HP and the channel width of the vertical channel portion VP may be the same as each other as a first width w.

Hereinafter, a channel length of a corresponding channel portion may indicate a length of the channel portion in an extension direction, and a channel width of a corresponding channel portion may indicate a width of the channel portion in a direction perpendicular to the extension direction. For example, the channel length of the horizontal channel portion HP may be the length of the horizontal channel portion HP in the first direction (the x-axis direction), and the channel width of the horizontal channel portion HP may be the width of the horizontal channel portion HP in the second direction (the y-axis direction). Likewise, the channel length of the vertical channel portion VP may be the length of the vertical channel portion VP in the second direction (the y-axis direction), and the channel width of the vertical channel portion VP may be the width of the vertical channel portion VP in the first direction (the x-axis direction).

The horizontal channel portions HP included in the first sub-area 1310 may form line symmetry with the vertical channel portions VP included in the second sub-area 1320 with respect to the virtual straight line VL. Likewise, the vertical channel portions VP included in the first sub-area 1310 may form line symmetry with the horizontal channel portions HP included in the second sub-area 1320 with respect to the virtual straight line VL. For example, the first horizontal channel portion HP1 included in the first sub-area 1310 may form line symmetry with the first vertical channel portion VP1 included in the second sub-area 1320 with respect to the virtual straight line VL.

According to one or more embodiments, the fourth direction DR4 may be a direction bisecting an angle made by the first direction (the x-axis direction) and the second direction (the y-axis direction). For example, when the first direction (the x-axis direction) and the second direction (the y-axis direction) are orthogonal to each other, the fourth direction DR4 may be oblique by about 45° with respect to the first direction (the x-axis direction) and the second direction (the y-axis direction).

According to one or more embodiments, the channel length of the horizontal channel portion HP and the channel length of the vertical channel portion VP, the horizontal channel portion HP and the vertical channel portion VP corresponding to each other, may be substantially the same as each other. Here, that the horizontal channel portion HP and the vertical channel portion VP correspond to each other indicates that the horizontal channel portion HP and the vertical channel portion VP form line symmetry with respect to the virtual straight line VL.

For example, if the channel length of the first horizontal channel portion HP1 is a first length L1, the channel length of the first vertical channel portion VP1 corresponding to the first horizontal channel portion HP1 may likewise be the first length L1. Thus, the sum of the channel lengths of the horizontal channel portions HP may be substantially the same as the sum of the channel lengths of the vertical channel portions VP.

FIG. 7 illustrates that the semiconductor layer Act may not be stretched or shrunk in any direction. When the first sub-area 1310 and the second sub-area 1320 included in the driving channel area 1300 are not deformed, the first sub-area 1310 and the second sub-area 1320 may form line symmetry with respect to the virtual straight line VL.

According to one or more embodiments, the display apparatus (or the substrate 100) may be stretched in at least one of the first direction (the x-axis direction) or the second direction (the y-axis direction). For example, the display apparatus may be stretched in the first direction (the x-axis direction), the second direction (the y-axis direction), or the first and second directions (the x-axis and y-axis directions). When the semiconductor layer Act is stretched or shrunk in a corresponding direction, the change in electrical characteristic caused by the deformation of the first sub-area 1310 may be offset or partially compensated for by the change in electrical characteristic caused by the deformation of the second sub-area 1320.

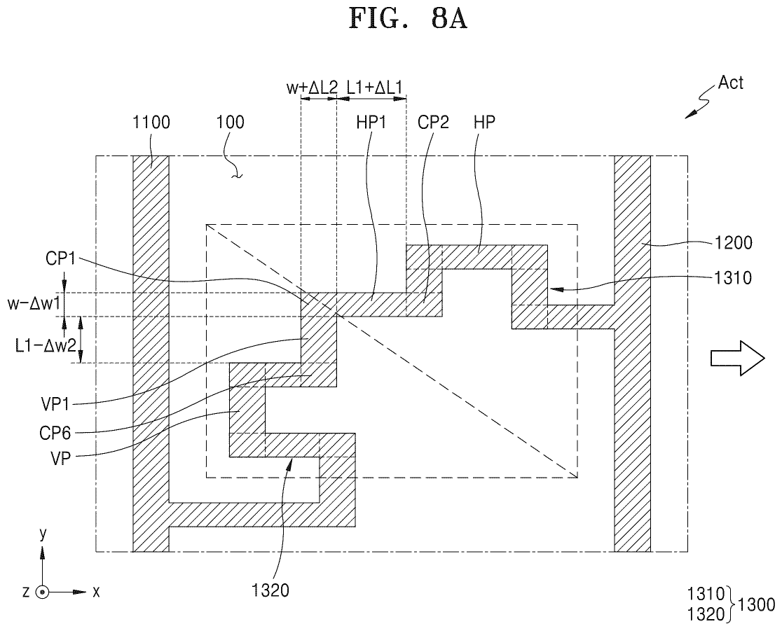

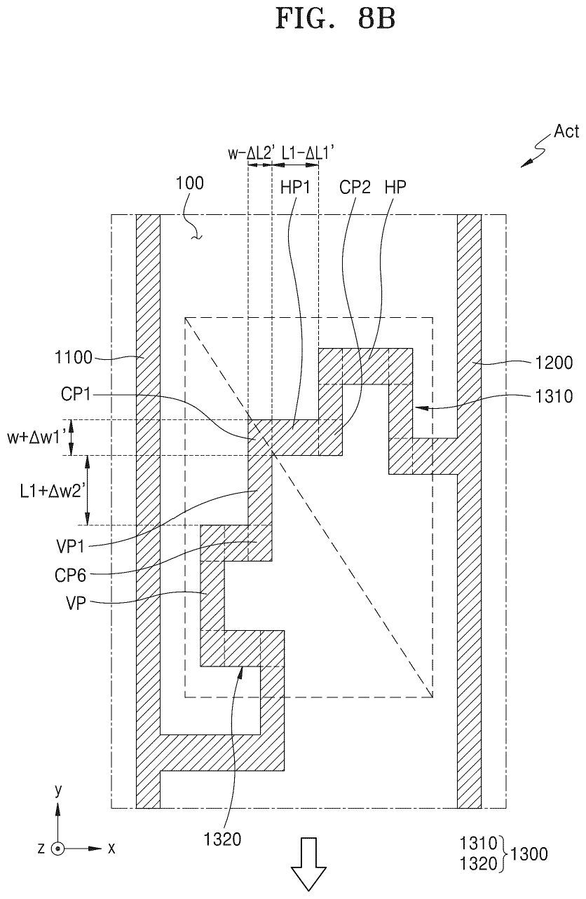

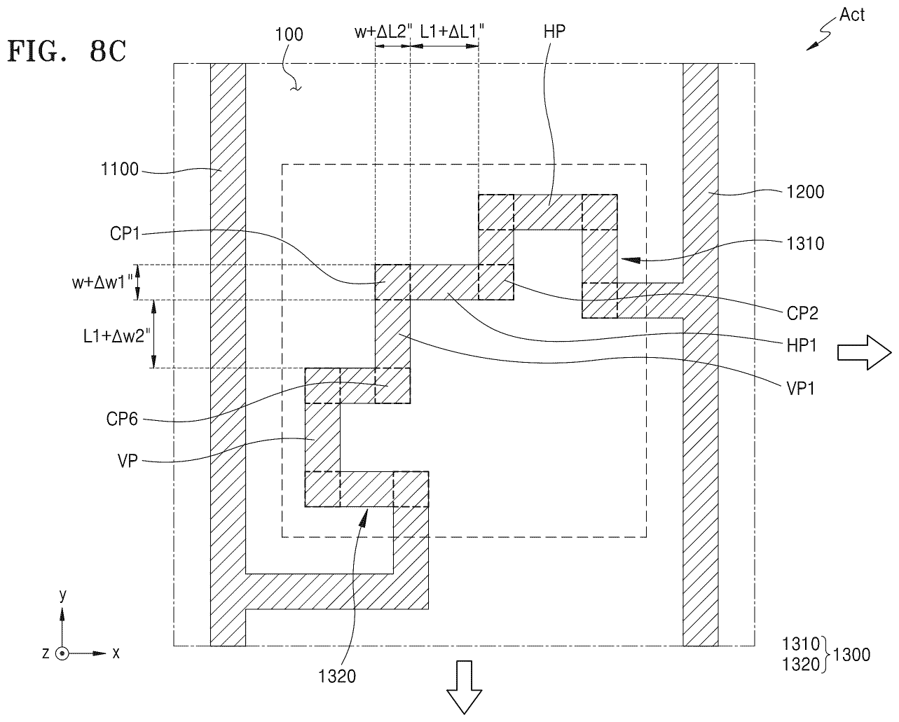

FIG. 8A is a plan view of the semiconductor layer Act of FIG. 7 stretched in the first direction, FIG. 8B is a plan view of the semiconductor layer Act of FIG. 7 stretched in the second direction, and FIG. 8C is a plan view of the semiconductor layer Act of FIG. 7 stretched in the first direction and the second direction.

Referring to FIG. 8A, the semiconductor layer Act may be stretched in the first direction (the x-axis direction). When the length of the semiconductor layer Act is increased in the first direction (the x-axis direction), the length of driving channel area 1300 may be increased in the first direction (the x-axis direction) and decreased in the second direction (the y-axis direction). Thus, if the semiconductor layer Act is stretched in the first direction (the x-axis direction), the channel length of each of the horizontal channel portions HP included in the driving channel area 1300 may be increased, and the channel length of each of the vertical channel portions VP included in the driving channel area 1300 may be decreased. The sum of the channel lengths of the horizontal channel portions HP may be increased, and the sum of the channel lengths of the vertical channel portions VP may be decreased. When the semiconductor layer Act is stretched in the first direction (the x-axis direction), the channel width of each of the horizontal channel portions HP included in the driving channel area 1300 may be decreased, and the channel width of each of the vertical channel portions VP included in the driving channel area 1300 may be increased.

For example, as described with reference to FIG. 7, if the semiconductor layer Act is not stretched, each of the first horizontal channel portion HP1 and the first vertical channel portion VP1 corresponding to each other may have the first length L1 and the first width w.

When the semiconductor layer Act is stretched in the first direction (the x-axis direction), the first horizontal channel portion HP1 may have a second length L1+ΔL1, which is increased from the first length L1 by a 1st-1 change amount ΔL1, and may have a second width w-Δw1, which is decreased from the first width w by a 2nd-1 change amount Δw1. The first vertical channel portion VP1 may have a third length L1-Δw2, which is decreased from the first length L1 by a 2nd-2 change amount Δw2, and may have a third width w+ΔL2, which is increased from the first width w by a 1st-2 change amount ΔL2. Here, the 1st-1 change amount ΔL1, the 1st-2 change amount ΔL2, the 2nd-1 change amount Δw1, and the 2nd-2 change amount Δw2 may have positive values.

A drain current of each channel portion may be proportional to the channel width, and may be inversely proportional to the channel length. When the semiconductor layer Act has an increased length in the first direction (the x-axis direction), the channel length of the first horizontal channel portion HP1 may be increased, and the channel width of the first horizontal channel portion HP may be decreased, and thus, the drain current of the first horizontal channel portion HP1 may be decreased. However, the channel length of the first vertical channel portion VP1 may be decreased and the channel width of the first vertical channel portion VP1 may be increased, and thus, the drain current of the first vertical channel portion VP1 may be increased. That is, the change in current characteristic due to the deformation of the first horizontal channel portion HP1 may be compensated for, or reduced by, the change in current characteristic due to the deformation of the first vertical channel portion VP1.

The driving channel area 1300 may include the first sub-area 1310 and the second sub-area 1320 that form line symmetry with respect to the virtual straight line VL, and thus, the horizontal channel portions HP and the vertical channel portions VP may respectively correspond to each other. Thus, the change in current characteristic due to the deformation of each horizontal channel portion HP may be offset or partially compensated for by the change in current characteristic due to the deformation of each vertical channel portion VP corresponding to the horizontal channel portion HP. Thus, even if the semiconductor layer Act is deformed, the electrical characteristics of the driving transistor including the driving channel area 1300 may seldom be changed.

Referring to FIG. 8B, the semiconductor layer Act may be stretched in the second direction (the y-axis direction). When the length of the semiconductor layer Act is increased in the second direction (the y-axis direction), the length of the semiconductor layer Act may be decreased in the first direction (the x-axis direction). With the deformation of the semiconductor layer Act, the length of the driving channel area 1300 may also be increased in the second direction (the y-axis direction) and decreased in the first direction (the x-axis direction). Thus, the channel length of each of the horizontal channel portions HP included in the driving channel area 1300 may be decreased, and the channel length of each of the vertical channel portions VP included in the driving channel area 1300 may be increased. The sum of the channel lengths of the horizontal channel portions HP may be decreased, and the sum of the channel lengths of the vertical channel portions VP may be increased. When the semiconductor layer Act is stretched in the second direction (the y-axis direction), the channel width of each of the horizontal channel portions HP included in the driving channel area 1300 may be increased, and the channel width of each of the vertical channel portions VP included in the driving channel area 1300 may be decreased.

For example, if the semiconductor layer Act is stretched in the second direction (the y-axis direction), the first horizontal channel portion HP1 may have a fourth length L1-ΔL1′, which is decreased from the first length L1 by a 3rd-1 change amount ΔL1′, and may have a fourth width w+Δw1′, which is increased from the first width w by a 4th-1 change amount Δw1′. The first vertical channel portion VP1 may have a fifth length L1+Δw2′, which is increased from the first length L1 by a 4th-2 change amount Δw2′, and may have a fifth width w-ΔL2′, which is decreased from the first width w by a 3rd-2 change amount ΔL2′. Here, the 3rd-1 change amount ΔL1′, the 3rd-2 change amount ΔL2′, the 4th-1 change amount Δw1′, and the 4th-2 change amount Δw2′ may have positive values.

When the semiconductor layer Act has an increased length in the second direction (the y-axis direction), the channel length of the first horizontal channel portion HP1 may be decreased and the channel width of the first horizontal channel portion HP may be increased, and thus, the drain current of the first horizontal channel portion HP1 may be increased. Here, because the channel length of the first vertical channel portion VP1 may be increased and the channel width of the first vertical channel portion VP1 may be decreased, and thus, the drain current of the first vertical channel portion VP1 may be decreased. Likewise, the change in current characteristic due to the deformation of each horizontal channel portion HP may be offset or partially compensated for by the change in current characteristic due to the deformation of each vertical channel portion VP corresponding to the horizontal channel portion HP.

Referring to FIG. 8C, the semiconductor layer Act may be stretched in the first direction (the x-axis direction) and the second direction (the y-axis direction). With the deformation of the semiconductor layer Act, the length of the driving channel area 1300 may also be increased in the first direction (the x-axis direction) and the second direction (the y-axis direction). Thus, the length and the width of each of the horizontal channel portions HP and each of the vertical channel portions VP included in the driving channel area 1300 may be increased.

For example, if the semiconductor layer Act is stretched in the first direction (the x-axis direction) and the second direction (the y-axis direction), the first horizontal channel portion HP1 may have a sixth length L1+ΔL1″, which is increased from the first length L1 by a 5th-1 change amount ΔL1″, and may have a sixth width w+Δw1″, which is increased from the first width w by a 6th-1 change amount Δw1″. The first vertical channel portion VP1 may have a seventh length L1+Δw2″, which is increased from the first length L1 by a 6th-2 change amount Δw2″, and may have a seventh width w+ΔL2″, which is increased from the first width w by a 5th-2 change amount ΔL2″.

According to the 5th-1 change amount ΔL1″, the 5th-2 change amount ΔL2″, the 6th-1 change amount Δw1″, and the 6th-2 change amount Δw2″, the drain current of the first horizontal channel portion HP1 may be increased or decreased. When the drain current of the first horizontal channel portion HP1 is increased, the drain current of the first vertical channel portion VP1 may be decreased, and if the drain current of the first horizontal channel portion HP1 is decreased, the drain current of the first vertical channel portion VP1 may be increased. Thus, the change in current characteristic due to the deformation of each of the horizontal channel portions HP may be offset or partially compensated for by the change in current characteristic due to the deformation of each of the vertical channel portions VP respectively corresponding to the horizontal channel portions HP.

As described with reference to FIGS. 8A to 8C, even if the semiconductor layer Act according to embodiments are stretched or shrunk in any direction of the first direction (the x-axis direction) and/or the second direction (the y-axis direction), the electrical characteristics of the driving transistor including the driving channel area 1300 may seldom be changed, or may be changed to a relatively small degree. Thus, in the display apparatus 1 (see FIG. 1), brightness deviation due to stretching of the display apparatus 1 may be reduced, and thus, a high-quality image may be provided.

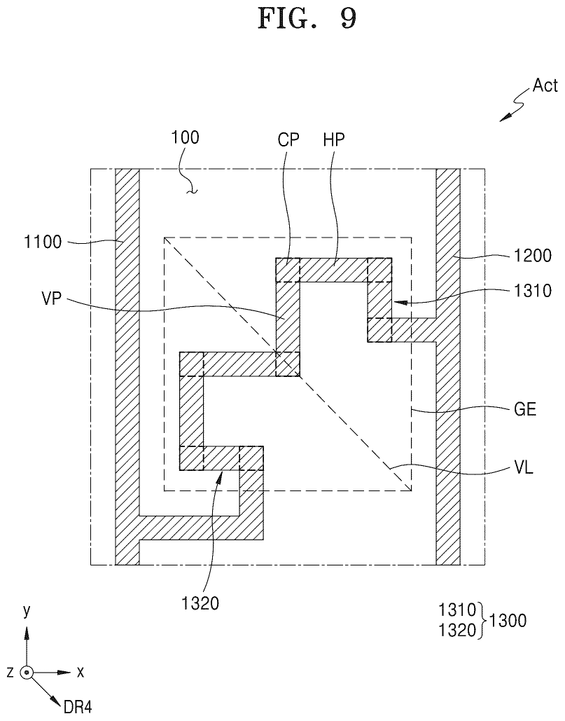

FIGS. 9 to 12 are respectively schematic plan views of a semiconductor layer Act of a display apparatus according to one or more embodiments.

FIGS. 9 to 12 schematically illustrate a plan view of the semiconductor layer Act in a third direction (a thickness and z direction), based on a driving channel area 1300 of a driving transistor and its peripheral areas, that is, a first area 1100 and a second area 1200. FIGS. 9 to 12 illustrate that the semiconductor layer Act may not be stretched or shrunk. In FIGS. 9 to 12, a gate electrode GE of the driving transistor, which is located on a different layer from the semiconductor layer Act, is projected.

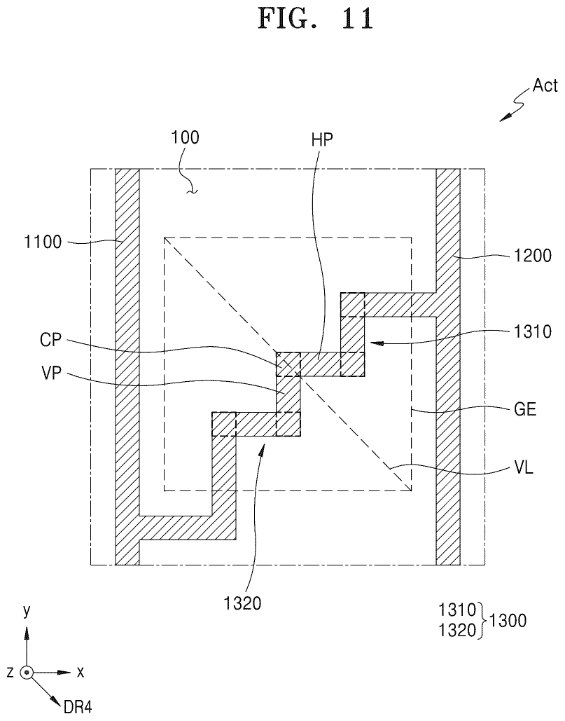

Referring to FIGS. 9 and 11, the semiconductor layer Act may include the first area 1100, the second area 1200, and the driving channel area 1300. Each of the first area 1100 and the second area 1200 may extend in a second direction (a y-axis direction). The first area 1100 and the second area 1200 may be apart from each other in a first direction (an x-axis direction), and the driving channel area 1300 may be arranged between the first area 1100 and the second area 1200.

The driving channel area 1300 may overlap the gate electrode GE in a plan view and may have a zig-zag shape. For example, the driving channel area 1300 may include horizontal channel portions HP extending in the first direction (the x-axis direction), vertical channel portions VP extending in the second direction (the y-axis direction), and crossing portions CP at which the horizontal channel portions HP and the vertical channel portions VP meet each other.

The crossing portions CP adjacent to each other in the first direction (the x-axis direction) may be connected to each other by the horizontal channel portions HP, and the crossing portions CP adjacent to each other in the second direction (the y-axis direction) may be connected to each other by the vertical channel portions VP. The horizontal channel portions HP and the vertical channel portions VP may be alternately arranged with the crossing portions CP therebetween. That is, one crossing portion CP may connect one horizontal channel portion HP to one vertical channel portion VP.

The driving channel area 1300 may include a first sub-area 1310 and a second sub-area 1320 forming line symmetry with respect to a virtual straight line VL extending in a fourth direction DR4. The fourth direction DR4 may cross the first direction (the x-axis direction) and the second direction (the y-axis direction). According to one or more embodiments, the fourth direction DR4 may be a direction bisecting an angle made by the first direction (the x-axis direction) and the second direction (the y-axis direction). For example, the first direction (the x-axis direction) and the second direction (the y-axis direction) may be orthogonal to each other, and the fourth direction DR4 may be oblique by about 45° in a clockwise direction with respect to the first direction (the x-axis direction). According to one or more other embodiments, the fourth direction DR4 may be oblique by about 45° in a counterclockwise direction with respect to the first direction (the x-axis direction).

The first sub-area 1310 and the second sub-area 1320 may be connected to each other at one crossing portion CP on the virtual straight line VL. Each of the first sub-area 1310 and the second sub-area 1320 may include at least two crossing portions apart from the virtual straight line VL. The number of horizontal channel portions HP, vertical channel portions VP, and crossing portions CP, the length of each of the horizontal channel portion HP, the vertical channel portion VP, and the crossing portion CP, and arrangement of the horizontal channel portions HP, the vertical channel portions VP, and the crossing portions CP may be variously designed such that the driving channel area 130 has a channel length corresponding to a driving range design of the driving transistor.

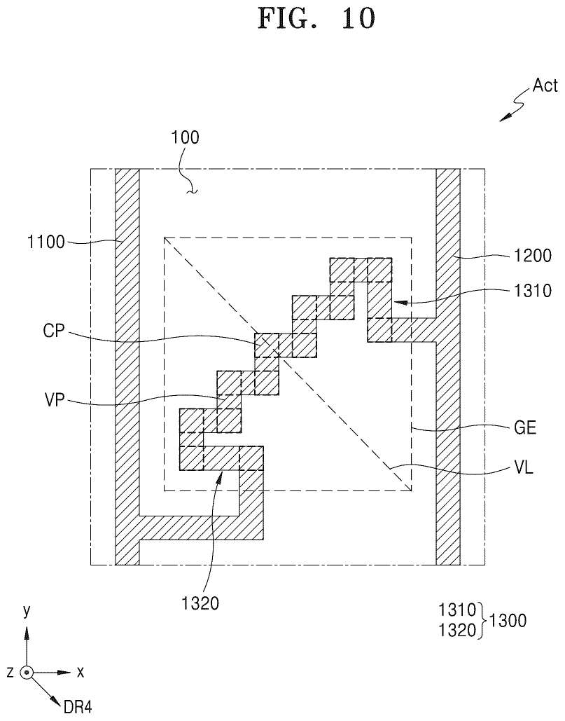

According to one or more embodiments, the driving channel area 1300 may have a shape substantially the same as inclined “Q” in a plan view. FIGS. 9 and 10 illustrate the driving channel area 1300 having the shape substantially the same as inclined “Q” in a plan view. FIG. 9 illustrates the driving channel area 1300 having fewer horizontal channel portions HP, vertical channel portions VP, and crossing portions CP than the driving channel area 1300 illustrated in FIG. 7. FIG. 10 illustrates the driving channel area 1300 having a greater number of horizontal channel portions HP, vertical channel portions VP, and crossing portions CP than the driving channel area 1300 illustrated in FIG. 7. The driving channel area 1300 may have curved portions whereby a distance between the driving channel area 1300 and the virtual straight line VL is decreased and then also increased. Thus, the driving channel area 1300 may have an increased channel length in a relatively small area.

According to one or more embodiments, at least a portion of the driving channel area 1300 may have a stair shape in a plan view. As illustrated in FIG. 11, the driving channel area 1300 may generally have a stair shape in a plan view.

In FIGS. 9 to 11, the crossing portions CP included in the first sub-area 1310 may form line symmetry with the crossing portions CP included in the second sub-area 1320. The horizontal channel portions HP included in the first sub-area 1310 may form line symmetry with the vertical channel portions VP included in the second sub-area 1320, and the vertical channel portions VP included in the first sub-area 1310 may form line symmetry with the horizontal channel portions HP included in the second sub-area 1320.

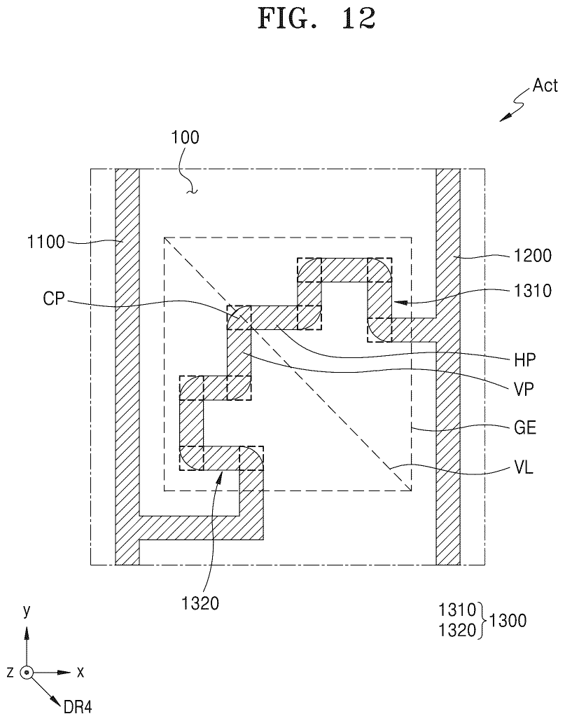

Referring to FIG. 12, the crossing portions CP may have an outer corner portion and an inner corner portion at which an edge of the driving channel area 1300 extending in the first direction (the x-axis direction) and an edge of the driving channel area 1300 extending in the second direction (the y-axis direction) meet each other. According to one or more embodiments, the outer corner portion of the crossing portions CP may have a round shape, or may be chamfered. According to one or more other embodiments, the inner corner portion of the crossing portions CP may have a round shape or may be chamfered. According to one or more other embodiments, the inner corner portion and the outer corner portion of the crossing portions CP may have round shapes, or may be chamfered.

When the outer corner portion and/or the inner corner portion of the crossing portions CP have/has the round shape or the chamfered shape, it is possible to prevent or reduce stress concentration at the outer corner portion and/or the inner corner portion of the crossing portions CP if the semiconductor layer Act is stretched or shrunk.

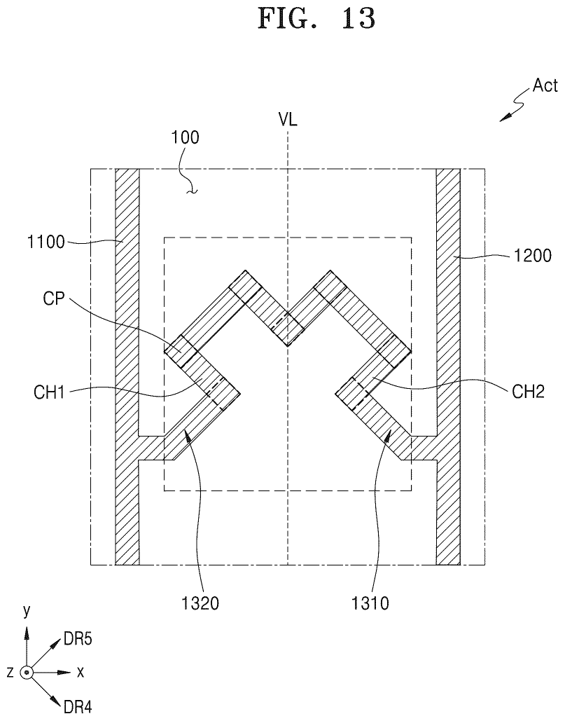

FIG. 13 is a schematic plan view of a semiconductor layer Act of a display apparatus according to one or more embodiments.

Referring to FIG. 13, the semiconductor layer Act may include a first area 1100, a second area 1200, and a driving channel area 1300. Each of the first area 1100 and the second area 1200 may extend in a second direction (a y-axis direction). Pixel circuits may be arranged to form a matrix in a first direction (an x direction) and in a second direction (a y direction).

The driving channel area 1300 may overlap a gate electrode GE in a plan view. To increase the channel length in a small area, the driving channel area 1300 may have a zig-zag shape in a plan view.

The driving channel area 1300 may include a first sub-area 1310 and a second sub-area 1320 forming line symmetry with respect to a virtual straight line VL extending in the second direction (the y-axis direction). According to one or more embodiments, the substrate 100 may be stretched or shrunk in at least one of a fourth direction DR4 or a fifth direction DR5 crossing a first direction (an x-axis direction) and the second direction (the y-axis direction). According to one or more embodiments, the fourth direction DR4 and the fifth direction DR5 may be orthogonal to each other. The fourth direction DR4 may be oblique by about 45° in a clockwise direction with respect to the first direction (the x-axis direction), and the fifth direction DR5 may be oblique by about 45° in a counterclockwise direction with respect to the first direction (the x-axis direction).

The driving channel area 1300 may include first channel portions CH1 extending in the fourth direction DR4, second channel portions CH2 extending in the fifth direction DR5, and crossing portions CP connecting the first channel portions CH1 to the second channel portions CH2.

The crossing portions CP may form line symmetry with respect to the virtual straight line VL. Any one of the crossing portions CP may be arranged on the virtual straight line VL. For example, the first channel portion CH1 of the second sub-area 1320 and the second channel portion CH2 of the first sub-area 1310 may be connected to each other at the crossing portion CP on the virtual straight line VL. That is, the first sub-area 1310 and the second sub-area 1320 may be connected to each other on the virtual straight line VL as a curved shape.

The crossing portions CP adjacent to each other in the fourth direction DR4 may be connected to each other by the first channel portions CH1, and the crossing portions CP adjacent to each other in the fifth direction DR5 may be connected to each other by the second channel portions CH2. One crossing portion CP may connect one first channel portion CH1 to one second channel portion CH2. In other words, the first channel portions CH1 and the second channel portions CH2 may be alternately arranged with the crossing portions CP therebetween.

According to one or more embodiments, the driving channel area 1300 may have a shape substantially the same as inclined “Q” in a plan view. The channel length of the driving channel area 1300 may be indicated as the sum of the channel length of each of the first channel portions CH1 and the channel length of each of the second channel portions CH2. Here, the length of the crossing portions CP may be disregarded. The channel length of the first channel portion CH1 may be the length of the first channel portion CH1 in the fourth direction DR4, and the channel width of the first channel portion CH1 may be the width of the first channel portion CH1 in the fifth direction DR5. The channel length of the second channel portion CH2 may be the length of the second channel portion CH2 in the fifth direction DR5, and the channel width of the second channel portion CH2 may be the width of the second channel portion CH2 in the fourth direction DR4.

The first channel portions CH1 included in the first sub-area 1310 may form line symmetry with the second channel portions CH2 included in the second sub-area 1320 with respect to the virtual straight line VL. The second channel portions CH2 included in the first sub-area 1310 may form line symmetry with the first channel portions CH1 included in the second sub-area 1320 with respect to the virtual straight line VL.

The display apparatus (or the substrate 100) may be stretched or shrunk in at least one of the fourth direction DR4 or the fifth direction DR5. When the semiconductor layer Act is stretched or shrunk in a corresponding direction, the change in electrical characteristic caused by the deformation of the first sub-area 1310 may be offset or partially compensated for by the change in electrical characteristic caused by the deformation of the second sub-area 1320.

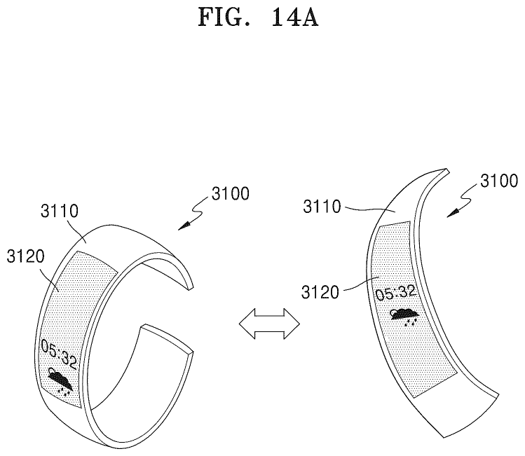

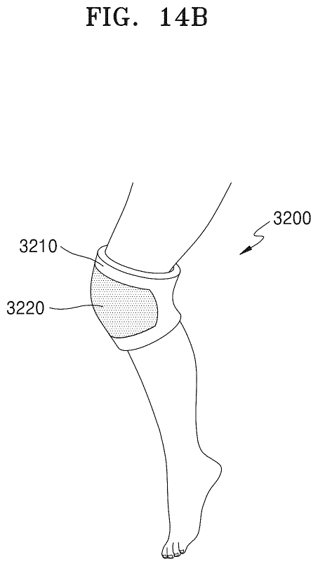

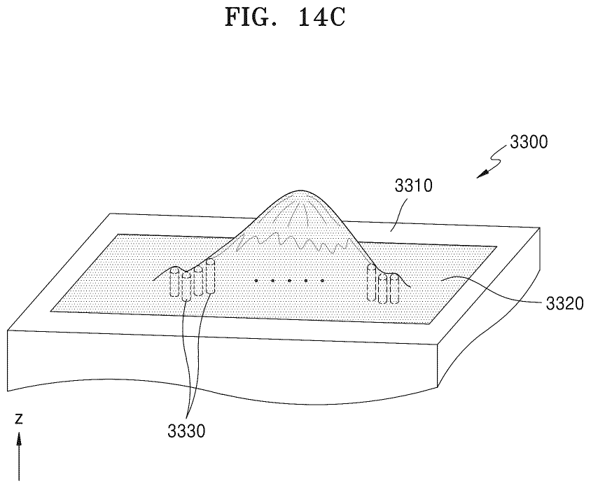

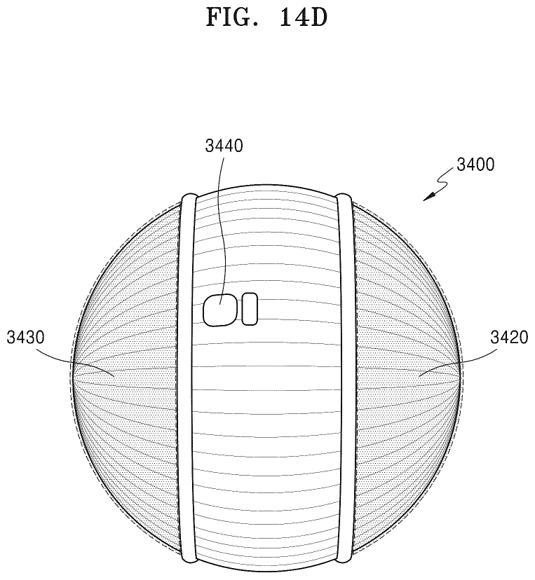

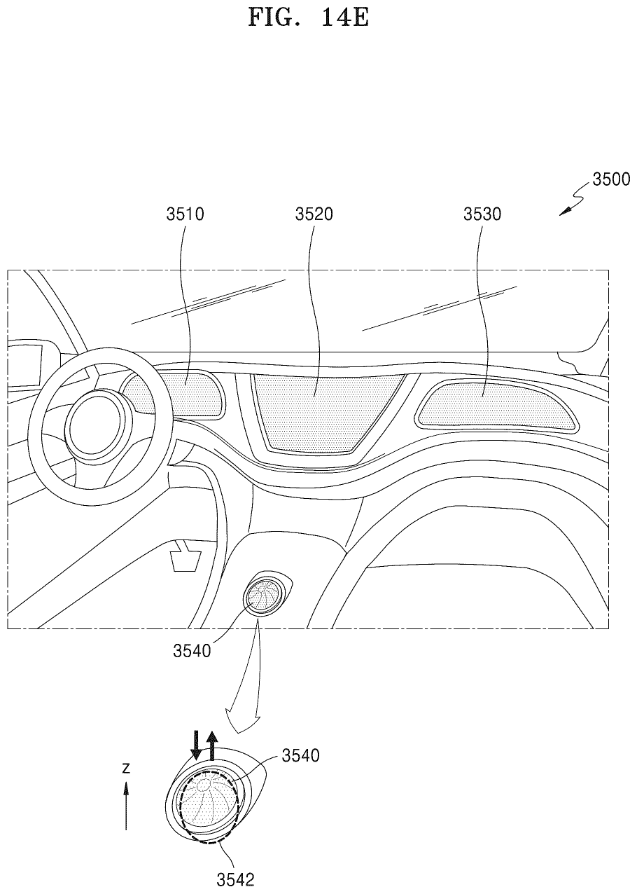

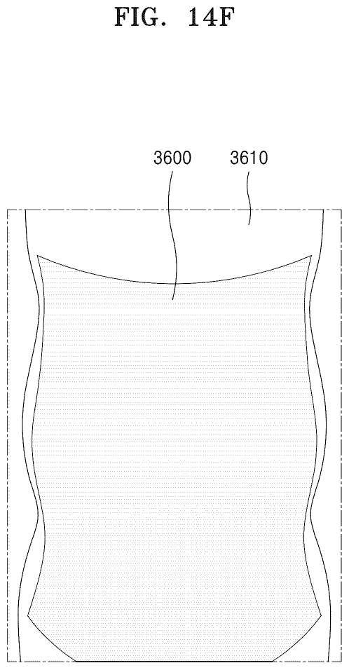

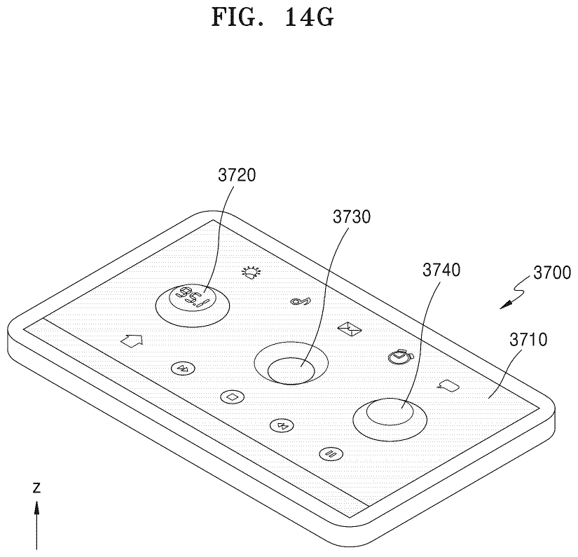

FIGS. 14A to 14G are respectively schematic perspective views of examples of an electronic device including a display apparatus according to one or more embodiments.

Referring to FIG. 14A, the display apparatus according to one or more embodiments may be used for a wearable electronic device 3100, which may be worn on a part of a human body of a user. The wearable electronic device 3100 may include a body 3110, and a display 3120 provided in the body 3110. The display apparatus according to embodiments may be used as the display 3120 of the wearable electronic device 3100. The wearable electronic device 3100 may be transformed, as illustrated in FIG. 14A. According to one or more embodiments, according to selection of a user, the wearable electronic device 3100 may be used as a smart watch or a smartphone.

FIG. 14B illustrates a medical electronic device 3200. According to one or more embodiments, the medical electronic device 3200 may include a body 3210 and an emission portion 3220. The display apparatus according to embodiments may be used as the emission portion 3220 of the medical electronic device 3200. The emission portion 3220 may emit light of a corresponding wavelength band (for example, infrared rays, visible rays, etc.) to a human body of a patient. According to one or more embodiments, the body 3210 may include a flexible fiber material, and may have a structure that is wearable on a human body of a user of the emission portion.

FIG. 14C illustrates an educational electronic device 3300. According to one or more embodiments, the educational electronic device may include a display 3320 provided in a frame 3310. The display 3320 may use the display apparatus according to embodiments. An image, such as the sea swelling with waves, mountains covered with snow, volcanoes with flowing lava, or the like may be provided through the display 3320, and in this case, the display 3320 may be stretched in a height direction (for example, a z direction) by reflecting the height of the waves, mountains, or volcanoes. According to one or more embodiments, a portion of the display 3320 may have a height that is sequentially variable along a direction in which the lava flows, thereby three-dimensionally showing the movement of the lava. The educational electronic device 3300 may include a plurality of pins (or strokes) 3330 arranged at a rear surface of the display 3320 so that the display 3320 may be stretched in a height direction. As the pins 3330 move in a third direction (for example, the z direction or a −z direction), an image represented by the display 3320 may be realized to have a three-dimensional height. FIG. 14C illustrates the educational electronic device 3300. However, the described usage is not limited thereto and may be applied to all devices providing corresponding image information.

It is described that the electronic devices illustrated in FIGS. 14A to 14C may have variable shapes. However, the disclosure is not limited thereto. As described according to embodiments below, the display apparatus according to embodiments may be used for an electronic device having a fixed portion (for example, a screen) configured to display an image.

FIG. 14D illustrates a robot 3400 as another electronic device according to one or more embodiments. The robot 3400 may recognize a movement or an object by using a camera 3440, and may display a corresponding image for a user through displays 3420 and 3430. According to one or more embodiments, the display apparatus according to embodiments may be stretched in various directions as described above, and thus, may be assembled into a body frame having a semicircular shape. Thus, the robot 3400 may include the displays 3420 and 3430 having semicircular shapes.

FIG. 14E illustrates a vehicle display device 3500 as an electronic device according to one or more embodiments. The vehicle display device 3500 may include a cluster 3510, a center information display (CID) 3520, and/or a co-driver display 3530. The display apparatus according to embodiments may be stretched in various directions, and thus, may not be limited by the shape of an internal frame of a vehicle and may be used for the cluster 3510, the CID 3520, and/or the co-driver display 3530.

FIG. 14E illustrates that the cluster 3510, the CID 3520, and/or the co-driver display 3530 are separate devices from each other. However, the disclosure is not limited thereto. According to one or more other embodiments, two or more selected from among the cluster 3510, the CID 3520, or the co-driver display 3530 may be integrally connected.

According to one or more embodiments, the vehicle display device 3500 may include a button 3540 configured to display a corresponding image. With reference to an enlarged view of FIG. 14E, the button 3540 having a semicircular shape may include an object 3542 providing a sense of use of a button by moving in a z direction or a −z direction and a display apparatus located above the object 3542. According some embodiments, if the object 3542 has a three-dimensionally round surface, the display apparatus may also have a three-dimensionally round surface.

FIG. 14F illustrates that the electronic device according to one or more embodiments may correspond to an electronic device 3600 for advertisement or exhibition. According to one or more embodiments, the electronic device 3600 for advertisement or exhibition may be mounted on a structure 3610 that is fixed, such as a wall or a pillar. When the structure 3610 includes a concavo-convex surface as illustrated in FIG. 14F, the electronic device 3600 for advertisement or exhibition may also be arranged along the concavo-convex surface of the structure 3610. According to one or more embodiments, the electronic device 3600 for advertisement or exhibition may be mounted on the structure 3610 by using a thermal contraction film, etc.

FIG. 14G illustrates that the electronic device according to one or more embodiments corresponds to a controller 3700. The controller 3700 may include an image-type button. For example, the controller 3700 may include first to third button areas 3720, 3730, and 3740 in which portions of a display 3710, protrude in a z direction, or protrude in a −z direction (e.g., are recessed from the z direction). According to one or more embodiments, the first and third button areas 3720 and 3740 may protrude in the z direction, and the second button area 3730 may protrude in the −z direction (or may be recessed from the z direction).

As described above, according to one or more embodiments, brightness deviation of pixels due to stretching of a display apparatus may be reduced, and thus, the display apparatus may display a high-quality image. However, the scope of the disclosure is not limited to the effect as described above.

It should be understood that embodiments described herein should be considered in a descriptive sense only and not for purposes of limitation. Descriptions of aspects within each embodiment should typically be considered as available for other similar aspects in other embodiments. While one or more embodiments have been described with reference to the figures, it will be understood by one of ordinary skill in the art that various changes in form and details may be made therein without departing from the spirit and scope as defined by the following claims, with functional equivalents thereof to be included therein.

What is claimed is:

1. A display apparatus comprising:
a substrate; and
a first transistor above the substrate, and comprising:
a first electrode; and
a semiconductor layer above or below the first electrode, and comprising a first channel area overlapping the first electrode and comprising a first sub-area and a second sub-area forming line symmetry with respect to a virtual straight line extending in a first direction, the first sub-area and the second sub-area comprising first channel portions having channel lengths in a second direction crossing the first direction, second channel portions having channel lengths in a third direction crossing the first direction and the second direction, and crossing portions connecting the first channel portions to the second channel portions.

2. The display apparatus of claim 1, wherein a sum of the channel lengths of the first channel portions is substantially equal to a sum of the channel lengths of the second channel portions.

3. The display apparatus of claim 1, wherein a channel width of the first channel portions is substantially equal to a channel width of the second channel portions.

4. The display apparatus of claim 1, wherein the first direction bisects an angle made by the second direction and the third direction.

5. The display apparatus of claim 4, wherein the second direction and the third direction are substantially orthogonal to each other.

6. The display apparatus of claim 1, wherein the substrate is configured to be stretched in at least one of the second direction or the third direction.

7. The display apparatus of claim 6, wherein the substrate comprises an elastomer.

8. The display apparatus of claim 6, wherein, in stretching the substrate in the second direction, a sum of the channel lengths of the first channel portions is increased, and a sum of the channel lengths of the second channel portions is decreased, and
wherein, in stretching the substrate in the third direction, the sum of the channel lengths of the first channel portions is decreased, and the sum of the channel lengths of the second channel portions is increased.

9. The display apparatus of claim 6, wherein, in stretching the substrate in the second direction, a channel width of the first channel portions is decreased and a channel width of the second channel portions is increased, and
wherein, in stretching the substrate in the third direction, the channel width of the first channel portions is increased and the channel width of the second channel portions is decreased.

10. The display apparatus of claim 1, further comprising a first insulating layer and a second insulating layer facing each other with the semiconductor layer therebetween,
wherein the first insulating layer and the second insulating layer comprise an elastomer.

11. The display apparatus of claim 10, wherein the semiconductor layer comprises an oxide-based semiconductor material or a silicon-based semiconductor material.

12. The display apparatus of claim 1, wherein the semiconductor layer comprises a stretchable semiconductor material.

13. The display apparatus of claim 12, wherein the semiconductor layer comprises a carbon nanotube or an organic semiconductor material.

14. The display apparatus of claim 1, wherein the first electrode comprises a stretchable conductive material.

15. The display apparatus of claim 14, wherein the first electrode comprises a conductive composite or a liquid metal material.

16. The display apparatus of claim 1, wherein at least a portion of the first channel area has a stair shape in a plan view.

17. The display apparatus of claim 1, further comprising a second transistor above the substrate, and comprising a second electrode overlapping the semiconductor layer,
wherein the semiconductor layer comprises a second channel area overlapping the second electrode, and
wherein a channel length of the second channel area is less than a channel length of the first channel area.

18. The display apparatus of claim 1, wherein the semiconductor layer further comprises a first area and a second area extending in the third direction, and spaced apart from each other in the second direction, and
wherein the first channel area is between the first area and the second area.

19. The display apparatus of claim 1, wherein the semiconductor layer further comprises a first conductive area and a second conductive area extending in the first direction, and spaced apart from each other in a fourth direction crossing the first direction, and
wherein the first channel area is between the first conductive area and the second conductive area.

20. The display apparatus of claim 1, further comprising a light-emitting diode electrically connected to the first transistor.
